(19) United States
(12) Patent Application Publication
(10) Pub. No.: US 2017/0087765 A1
(43) Pub. Date: Mar. 30, 2017

(54) COLOR AND/OR OPACITY CHANGING LIQUID RADIATION CURABLE RESINS, AND METHODS FOR USING THE SAME IN ADDITIVE FABRICATION

(71) Applicant: DSM IP Asset B.V., Heerlen (NL)

(72) Inventors: Beth RUNDLETT, Norwalk, IA (US); Brett REGISTER, Wonder Lake, IL (US)

(21) Appl. No.: 15/126,299

(22) PCT Filed: Mar. 25, 2015
(86) PCT No.: PCT/US15/22407

§ 371 Date: Sep. 15, 2016

(51) Int. Cl. B29C 67/00; B33Y 70/00; G03F 7/105; G03F 7/16; G03F 7/20; G03F 7/095; B29C 35/08; B33Y 10/00

(52) U.S. Cl. CPC B29C 67/007; B29C 35/0805; B33Y 70/00; B33Y 10/00; G03F 7/16; G03F 7/2002; G03F 7/2022; G03F 7/095; G03F 7/105; B29C 2035/0833; B29K 2995/0021; B29K 2105/0032

(57) ABSTRACT

Color and/or opacity changing liquid radiation curable resins are herein described, along with methods for using the same in additive fabrication processes. Described and claimed are methods for improving additive fabrication build processes by controlling, at least temporarily, the depth of penetration of a liquid radiation curable resin. The liquid radiation curable resins herein described are capable of curing into three-dimensional articles having a certain amount of color and/or opacity. The resulting three-dimensional articles possess an ability to further change in color and/or opacity, and possess excellent mechanical properties. Also herein described are the three-dimensional articles formed according to the methods of the invention.

### CROSS-REFERENCE TO RELATED APPLICATIONS

This application claims the benefit of the filing date of U.S. Provisional Patent Application No. 61/970,435 filed Mar. 26, 2015, the disclosure of which is hereby incorporated herein by reference.”

### BACKGROUND OF THE INVENTION

Additive fabrication processes for producing three dimensional articles are known in the field. Additive fabrication processes utilize computer-aided design (CAD) data of an object to build three-dimensional parts layer-by-layer. These three-dimensional parts may be formed from liquid resins, powders, or other materials.

A non-limiting example of an additive fabrication process is stereolithography (SL). Stereolithography is a well-known process for rapidly producing models, prototypes, patterns, and production parts in certain applications. SL uses CAD data of an object wherein the data is transformed into thin cross-sections of a three-dimensional object. The data is loaded into a computer which controls a laser beam that traces the pattern of a cross section through a liquid radiation curable resin composition contained in a vat, solidifying a thin layer of the resin corresponding to the cross section. The solidified layer is recoated with resin and the laser beam traces another cross section to harden another layer of resin on top of the previous layer. The process is repeated layer by layer until the three-dimensional object is completed. When initially formed, the three-dimensional object is, in general, not fully cured and therefore may be subjected to post-curing, if required. An example of an SL process is described in U.S. Pat. No. 4,575,330.

The liquid radiation curable resin used in stereolithography and other additive fabrication processes for forming three-dimensional objects can be solidified by light energy. Typically, liquid radiation curable resins are cured by ultra-violet (UV) light. Such light is typically produced by lasers (as in stereolithography), lamps, or light emitting diodes (LEDs). See PCT Patent Application PCT/US10/60677, filed on Dec. 16, 2010, and incorporated by reference in its entirety. The delivery of energy by a laser in a stereolithography system can be Continuous Wave (CW) or Q-switched pulses. CW lasers provide continuous laser energy and can be used in a high speed scanning process.

With some known resins, the final color and/or clarity of the cured three dimensional part is not substantially different from that of the resin from which it was formed. However with others, it is typical that the final color and/or clarity develops in the three dimensional article as it is cured. Some known resins may be clear in liquid forms and form opaque three-dimensional articles upon cure. Other known resins may be colorless in liquid form and capable of curing into colored three-dimensional articles. Furthermore, some resins appear as a first color in liquid form and turn a second color upon cure.

Throughout this patent application the term color is defined as follows: color (or colour, alternative spelling) is the visual perceptual property corresponding in humans to the categories called red, yellow, green, etc. Color derives from the spectrum of light (distribution of light energy versus wavelength) interacting in the eye with the spectral sensitivities of the light receptors. Color categories and physical specifications of color are also associated with objects, materials, light sources, etc., based on their physical properties such as light absorption, reflection, or emission spectra. Typically, only features of the composition of light that are detectable by humans are included, thereby objectively relating the psychological phenomenon of color to its physical specification.

Color and transparency are two distinct principles. For instance, something may visually appear perfectly clear and still colored. For instance, certain colored glass is entirely transparent to the eye and possesses a color. Similarly, something may be colorless and also clear or opaque. Colorless is defined as lacking all color. For instance, pure liquid water is clear and colorless. An article that is visually perceived as perfectly clear and as a color, for instance, blue, is reflecting the blue color while allowing all other wavelengths of light to pass through. When a viewer perceives white, the article will appear less transparent because all colors are being reflected back at the viewer and thus not passing through the article.

In recent years, the demand for liquid radiation curable resins that produce three-dimensional articles that have excellent dimensional accuracy, shape stability, mechanical properties, and the like has increased. Along with this development, demand has grown for three-dimensional articles that possess a desired color or transparency/opacity, and also have the mentioned excellent properties. These colored three-dimensional articles are useful because they are aesthetically pleasing, can mimic the appearance of commercial materials, and may possess light-shielding properties. Along with this development, the demand for radiation-curable compositions in which the color or opacity can be altered has increased.

Liquid radiation curable resins which enable selectively controllable color and opacity during curing are described in U.S. Patent Pub. No. 2012/0295077, which is hereby incorporated in its entirety.

Meeting the challenges of producing selectively colored three-dimensional articles is also described in U.S. Pat. No. 6,133,336. This patent describes a method of curing and adding color to a three-dimensional article using light at a single wavelength, and at a lower and a higher dose. The lower dose of light is used to cure the liquid resin to form a solid and the higher dose of light is used to add color to the resin. The process claimed is only for adding color, not removing color. This patent also claims a composition for a photocurable and photocolorable resin. However, the disclosed composition has poor mechanical properties and poor color stability. For instance, after initial curing, the uncolored sections of the article become colored over time in ambient light. Such problems are common with photoresponsive coloring techniques.

U.S. Pat. No. 5,677,107 discloses a method for preparing and selectively coloring a three-dimensional article by adding or removing color. The coloring agent is photoresponsive and the method claimed is dependent on using a photoresponsive coloring agent.

U.S. Pat. No. 5,942,554 discloses a method of effecting color change in polymeric bodies of either thermal curable or photocurable resins. The color-changing compound is sensitive to acid produced during polymerization of the resin. The acid is produced from the initiating species which are activated by either light or temperature. The color change occurs when the coloring agent is exposed to the acid.

U.S. Pat. No. 6,664,024 discloses a photocurable resin composition for forming three-dimensional objects that can be selectively colored that utilizes a photoactivated coloring compound.

U.S. Pat. No. 6,649,311, assigned to Vantico Limited, discloses a resin for use in forming three-dimensional objects that can use a photosensitive coloring compound contained in microcapsules. Similarly, U.S. Published Patent Application No. 2004/0076909 discloses a liquid resin composition for use in forming three-dimensional objects which comprises particles dispersed in the composition which are micro-capsules containing a photosensitive color changing composition.

U.S. Published Patent Application No. 2004/0170923, assigned to 3D Systems, Inc., discloses colored resins useful in forming three-dimensional objects; however, such resins cannot be selectively colored by exposure to various doses of light.

U.S. Pat. No. 6,746,814, assigned to the inventor, discloses a method for selectively coloring or shading an article produced by overexposing the liquid resin to radiation during cure and then heating the entire model with an effective amount of heat in order to induce a color change in the overexposed sections of the article. No coloring or transparency modifying agent is used.

All else being equal, colored and opaque resins typically possess a lower depth of penetration (Dp) than do equivalent colorless or transparent resins. Depth of penetration is a measure of how deep visible light or any actinic radiation can penetrate into a material. It is defined as the depth at which the intensity of the radiation inside the material falls to 1/e (or approximately 37%) of its original value at or just beneath the surface. If the Dp of the material becomes too low, the light cannot penetrate a layer of material deep enough to form a sufficiently cured layer. This disruption in the necessary photopolymerization process is especially apparent in opaque or deeply colored resins (such as black or dark blue), which necessarily possess a lower Dp.

Black or nearly black resins have existed in additive fabrication applications operating via photopolymerization, such as stereolithography. However they have been notoriously difficult to operate in such additive fabrication applications for a variety of reasons. First, because of their inherent dark color and/or opacity, their associated Dp is less than that for ideal suitability in additive fabrication via photopolymerization. Even those with relatively less black color, their opacity and/or color necessitate an increased energy dose to undergo polymerization than do similarly-formulated clear, colorless resins. This results in either: (1) an increase in energy consumption required to build a particular part, due to increased intensity demands on the light source, or (2) an increased build time of the three-dimensional cured part, because a longer exposure time is required to complete polymerization of a given layer. These factors increase the cost, and even feasibility, associated with building opaque or deeply colored resins.

Such resins still typically yield inaccurate cured parts, or ones with insufficient mechanical properties, due to the inability of light to properly cure the liquid resin.

Additionally, heretofore few if any black resins for additive fabrication processes have been successfully used because of an additional difficulty associated with their use via photopolymerization. Such resins contain black or darkly colored pigments or dyes which inherently have a tendency to absorb most or all incoming light, such as the incoming light from a source of actinic radiation used to cure the resin in additive fabrication processes. This absorption reduces the amount of light available for the photoinitiators, thereby limiting the number of cationic and/or free-radical species generated, often to a level unacceptable for the required polymerization process.

Furthermore, resins which use a latent coloring component to impart a dark or black color to the resin after curing do not allow for further color changes and are not reversible. Additionally, the color effect is not always imparted uniformly or with a desired color intensity.

It would therefore be desirable to develop a liquid radiation curable resin that can cure into a three-dimensional article having desired black or darkly-colored properties, while obviating the heretofore unsolved associated problems associated with building via additive fabrication the inherently low-Dp dark or opaque resins. Further, it would be desirable to develop a liquid radiation curable resin that could repeatably and reversibly change colors from a colorless to a richly or darkly colored state in response to changing conditions, while still having excellent mechanical properties.

### SUMMARY OF THE INVENTION

The first aspect of the instant claimed invention is a method of forming a three-dimensional article via additive fabrication comprising: (1) inducing an increase in a depth of penetration (Dp) of a radiation curable resin, thereby forming a radiation curable resin having an increased Dp; (2) establishing a layer of the radiation curable resin having the increased Dp; (3) exposing the layer imagewise to actinic radiation to form an imaged cross-section, thereby forming a cured layer; (4) forming a new layer of radiation curable resin having the increased Dp in contact with the cured layer; (5) exposing said new layer imagewise to actinic radiation to form an additional cured layer; and (6) repeating steps (4) and (5) a sufficient number of times in order to build up a three-dimensional article.

The second aspect of the instant claimed invention is a method of forming via additive fabrication a three-dimensional article capable of changing color comprising: (1) heating a liquid radiation curable resin, thereby forming a liquid radiation curable resin having an increased depth of penetration (Dp); (2) establishing a first liquid layer of the liquid radiation curable resin having the increased Dp; (3) exposing the first liquid layer imagewise to actinic radiation to form an imaged cross-section, thereby forming a first cured layer; (4) forming a new layer of liquid radiation curable resin having the increased Dp in contact with the first cured layer; (5) exposing said new layer imagewise to actinic radiation to form an additional cured layer; and (6) repeating steps (4) and (5) a sufficient number of times in order to build up a three-dimensional article; wherein the liquid radiation curable resin further comprises at least one thermochromic component having an activation temperature and a terminal activation temperature, such that the thermochromic component changes from a colored state to a partially colored state at the activation temperature, and to a substantially colorless state at the terminal activation temperature; and at least one non-thermochromic pigment or dye, such that the liquid radiation curable resin or three-dimensional article changes from a first colored state to a second colored state at the activation temperature, and to a third colored state at the terminal activation temperature.

The third aspect of the instant claimed invention is a method of forming via additive fabrication a three-dimensional article capable of color or opacity change comprising: (1) inducing an at least temporary change in a depth of penetration (Dp) of a liquid radiation curable resin, thereby forming a liquid radiation curable resin having an at least temporarily modified Dp, wherein the temporary change in the Dp is occasioned by subjecting the liquid radiation curable resin to an alteration in an environmental condition selected from the group consisting of heat, light, pH, magnetism, pressure, and electric current; (2) establishing a first liquid layer of the liquid radiation curable resin having the at least temporarily modified Dp; (3) exposing the first liquid layer imagewise to actinic radiation to form an imaged cross-section, thereby forming a first cured layer; (4) forming a new layer of liquid radiation curable resin having the at least temporarily modified Dp in contact with the first cured layer; (5) exposing said new layer imagewise to actinic radiation to form an additional imaged cross-section; and (6) repeating steps (4) and (5) a sufficient number of times in order to build up a three-dimensional article; wherein the liquid radiation curable resin further comprises a first visual effect initiator having a first activation point; such that during step (1), the first visual effect initiator component reaches the first activation point, thereby inducing a color or opacity change in the liquid radiation curable resin.

The fourth aspect of the instant claimed invention is a three-dimensional object formed by the method of the first, second, or third aspect of the instant claimed invention.

### DETAILED DESCRIPTION OF THE INVENTION

Throughout this patent application, a visual effect initiator is defined as a component capable of incorporation into a liquid radiation curable resin that can be used to form three-dimensional objects and that is capable of imparting a change in the color or opacity of the liquid radiation curable resin, as well as the cured three-dimensional article made therefrom, in response to an alteration of an environmental condition. Such conditions include, as non-limiting examples, a change in temperature, light, pH, magnetism, pressure, and electric current.

The activation point of a visual effect initiator is defined as the point along the range of a specific environmental condition at which the visual effect initiator begins to exhibit a color and/or opacity change. For example, a visual effect initiator which is responsive to changes in pH might start to transform from transparent to an increased amount of opacity if the alkalinity of the solution in which it is immersed is increased to 8.0. Similarly, a visual effect initiator which is responsive to changes in electric current might begin to transform from a red color towards a state of reduced red color if an electric current of above 10 milliamperes were imparted to the visual effect initiator.

The terminal activation point of a visual effect initiator is defined as the point along the range of a specific environmental condition at which the visual effect initiator completes a color and/or opacity change. For example, a visual effect initiator which is responsive to changes in pH might reach a completely opaque state (that is, approximately allowing 0% light transmission therethrough) if the alkalinity of the solution in which it is immersed is increased to 10.0. Further increases in the pH beyond this point would not yield further changes to the visual state of the resin into which the visual effect initiator were immersed. Similarly, a visual effect initiator which is responsive to changes in electric current might reach a completely colorless state if the electric current of 15 milliamperes were imparted to the visual effect initiator. Further increases in the current would not yield additional changes to the visual state of the resin into which the visual effect initiator were immersed.

A colored state is defined herein as a visual state in which a certain amount of color is exhibited by a visual effect initiator. A partially colorless state is defined as a visual state in which a visual effect initiator exhibits a measurably lower amount of color than it does in a colored state. That is, it absorbs a measurably lower amount of visible light in the region between approximately 390 nm and 780 nm. The terms colored state and partially colored state are relative, and may be different for different objects. However, in all such cases, for a given object, the amount of color exhibited during the partially colorless state is necessarily lower than it is in the colored state.

Such a change from a colored state to a partially colorless state, or a change from a partially colorless state to a colored state, may be occasioned by subjecting the visual effect initiator to an alteration of an environmental condition to which the visual effect initiator is responsive, to a level at an activation point or terminal activation point.

A substantially colorless state, meanwhile, is defined as a state in which the object (component, resin, or three-dimensional article) shows an absorbance of visible light in the region between approximately 390 nm and 780 nm of less than 0.2, measured on a sample having a thickness of 1 cm, when absorbance is measured on a UV-VIS spectrophotometer in accordance with ASTM E1164-94. Further methods of measuring color are discussed in US 20030149124, assigned to the Applicant, which is hereby incorporated by reference.

A certain class of visual effect initiators are responsive to changes in temperature. Thermochromic components constitute a non-limiting subset of such visual effect initiators. A thermochromic component is defined herein as a component capable of incorporation in a liquid radiation curable resin that changes the amount of color and/or opacity exhibited in response to a change in temperature. Thermochromic components have the ability to impart a change in the amount of color and/or opacity exhibited in the liquid radiation curable resin into which they are immersed, and similarly are capable of imparting a change in the amount of color and/or opacity exhibited in the three-dimensional part cured therefrom.

The activation temperature of a thermochromic is defined as the temperature at which it begins to exhibit a color and/or opacity change. For example, a thermochromic component which is capable of color change from black to colorless might appear black at temperatures of below 31 degrees Celsius. At this hypothetical activation temperature of 31 degrees Celsius, such a thermochromic component would begin to exhibit a color change from black to colorless.

The terminal activation temperature of a thermochromic component is the temperature at which the color and/or opacity change is completed. Further changes in temperature beyond the terminal activation temperature in a direction away from the activation temperature will yield no further changes to the visual state of the thermochromic component. For example, a thermochromic component which is capable of color change from black to colorless might appear black at temperatures of below 31 degrees Celsius. At its hypothetical activation temperature of 31 degrees Celsius, such a thermochromic component would begin to exhibit a color change from black to colorless. As the temperature is increased, the component would exhibit gradually decreasing amounts of black color. Finally, at a hypothetical terminal activation temperature of 35 degrees Celsius, such a thermochromic component would appear completely colorless. Further increases in the temperature would yield no further changes to the visual state of the thermochromic component.

The locking temperature of a thermochromic component is the temperature at which any change in color and/or opacity will be permanent or semi-permanent. Permanent color and/or opacity change is irreversible. Semi-permanent color and/or opacity change is reversible under certain circumstances; i.e. to reverse the color change, the thermochromic component might have to be cooled to significantly below room temperature. Non-permanent color and/or opacity change is any change that occurs that is not permanent or semi-permanent. Non-permanent color and/or opacity change is reversible. Thermochromic components lacking a locking temperature are non-permanent and can impart reversible color and/or opacity changes into the liquid radiation curable resin into which they are immersed, along with the three-dimensional part cured therefrom.

A thermally sensitive transparency modifier is a component capable of incorporation into a liquid radiation curable resin that has the ability to change the transparency of a liquid radiation curable resin or a three dimensional article made therefrom due to a change in temperature. The transparency is typically changed by modifying the light scattering properties of the selectively cured section of the three-dimensional article produced from a liquid radiation curable resin. A thermochromic component can also be a thermally sensitive transparency modifier and a thermally sensitive transparency modifier can also be a thermochromic component. In fact, even a component that is substantially thermochromic will often also affect the visual transparency of the three-dimensional article in some small way. A thermally sensitive visual effect initiator may be a thermochromic component, a thermally sensitive transparency modifier, or both.

Throughout this patent application, individual colors are defined according to a discrete range of measurable electromagnetic radiation wavelengths through a vacuum. As such, an object that is violet reflects light through a medium which is a vacuum of a wavelength of from 390 nm to 455 nm. Under the same conditions, blue is defined as from greater than 455 nm to 492 nm, green is defined as from greater than 492 nm to 577 nm, yellow is defined as from greater than 577 nm to 597 nm, orange is defined as from greater than 597 nm to 622 nm, and red is defined as from greater than 622 nm to 780 nm. An object that is white reflects all visible light.

Throughout this patent application, a microcapsule is a particle of less than 500 micrometers capable of encapsulating other components. The heat of polymerization of the resin is the heat given off by the exothermic reaction of polymerization. Intensity is defined as the time-averaged power per unit area. Dose is the total power per unit area.

The first aspect of the instant claimed invention is a method of forming a three-dimensional article via additive fabrication comprising: inducing an increase in a depth of penetration (Dp) of a radiation curable resin, thereby forming a radiation curable resin having an increased Dp; establishing a layer of the radiation curable resin having the increased Dp; exposing the layer imagewise to actinic radiation to form an imaged cross-section, thereby forming a cured layer; forming a new layer of radiation curable resin having the increased Dp in contact with the cured layer; exposing said new layer imagewise to actinic radiation to form an additional cured layer; and repeating the forming and exposing steps a sufficient number of times in order to build up a three-dimensional article.

In forming a first cured layer, appropriate imaging radiation is radiation applied which is sufficient to cure a liquid radiation curable resin layer by layer in order to form a three-dimensional article. The energy dose and intensity required to form cured layers is well-known to those having skill in the art. A layer may be of any suitable thickness and shape, and is dependent on the additive fabrication process utilized. For example, it may be selectively dispensed via jetting, or it may be added by dipping the previously cured layer into a vat of resin, producing a layer of substantially uniform thickness, as is typical with most stereolithography processes.

From the foregoing background description, it is apparent that color and opacity-changing resins have been used in additive fabrication processes for some time. Many such resins are colored selectively colorable, but such coloration or selective coloration is typically irreversible. Inventors have identified that reversible color-changing resins would be very useful in the prototyping industry. For example, if a resin existed which could form three-dimensional articles which readily and reversibly changed colors in response to gradually changing external conditions, valuable real-time feedback could be provided to engineers. Specifically, a resin which could form three-dimensional articles which gradually and reversibly changed in response to changing temperatures would be useful to determine at what points or locations a part cured by way of additive fabrication was heating up (perhaps due to increased friction), potentially indicating design flaws. Further, such “smart-parts” could provide such feedback without the need for expensive monitoring equipment, such as thermal imaging cameras. This would decrease cost and increase effectiveness of thermal testing currently performed in the automotive, aerospace, and nautical industries.

Additionally, there exists a particularly unmet demand for liquid radiation curable resins ideally suitable for use in additive fabrication processes which produce richly or darkly colored three-dimensional cured parts. Currently, a relatively sparse number of color options for liquid radiation curable resins for additive fabrication are commercially available, particularly in resins which form three-dimensional articles via photopolymerization. Although a select few color variants exist, the industry is typically constrained to resins producing three-dimensional cured parts which are largely transparent, colorless, or both. And even where darkly or richly colored resins have been commercially offered, they failed to achieve widespread use in the industry due to the known problems associated with their use.

Inventors have discovered it is possible to produce richly or darkly colored three-dimensional parts which are easily workable in additive fabrication processes, particularly those involving photopolymerization, by overcoming the problems heretofore associated with their use. In so doing, Inventors have found a way to additionally impart the “smart-part” benefits of color- or opacity-changing three-dimensional parts cured therefrom.

It is well appreciated that not all liquid radiation curable resins for additive fabrication possess equivalent suitability for curing. Various resins exhibit varying levels of viscosity, opacity, and color, among many other characteristics. Such factors will influence the ability of light to penetrate to a certain depth, as well as the amount of energy required to cure a layer of resin at such a depth. All else being equal, resins with lower depth of penetration (Dp) values will necessarily require a greater amount of actinic radiation to cure any given layer of a defined depth. Those having skill in the art have traditionally accounted for this inherent characteristic of the resin by altering the build parameters associated with an additive manufacturing machine. In stereolithography machines, for example, this may be performed by increasing the intensity of the actinic radiation source, increasing the duration of time during which any given portion of the liquid radiation curable resin is exposed to such actinic radiation, by adjusting the focal parameters of the light source, or by altering the part's programmed layer thickness.

Inventors have discovered, however, that the Dp of a given resin need not be static or immutable. By inducing certain changes in various environmental conditions to a liquid radiation curable resin for additive fabrication, inventors have discovered that it is possible, if at least temporarily, to alter that resin's Dp. By inducing a desired change to a resin's Dp while it is in the liquid state prior to curing, it is possible to significantly improve the energy efficiency, accuracy, and speed with which a three dimensional part may be cured. More specifically, by increasing the Dp of a resin, the amount of radiation intensity required to form an additional imaged cross-section during an additive fabrication process is reduced when compared with a similarly-formulated resin in which the Dp had not been so increased.

Many resins which are darkly or richly colored, such as black or dark blue, for example, or those which are substantially opaque, typically possess lower Dp values than do otherwise similarly-formulated colorless or clear resins. That is, the light transmission through a predefined layer of such colored or opaque resins is low, in large part due to the presence of the very light-reflecting or absorbing particles which impart the desired color or opacity. By controlling the Dp of such resins, it is possible to mitigate or eliminate the effects of the color or opacity-imparting particles such that their suitability for use in additive fabrication processes is comparable of that to of clear and/or colorless resins.

Inventors have discovered that certain resins possess dynamic Dp values which are responsive to alterations in environmental conditions, such as temperature, pH, light, pressure, magnetism, or electric current. In an embodiment, resins with dynamic Dp values possess a visual effect initiator having an activation point. In an embodiment the visual effect initiator also possesses a terminal activation point. In another embodiment, the visual effect initiator is a thermochromic component having an activation temperature. In an embodiment the thermochromic component also has a terminal activation temperature.

For darkly or richly colored resins, or those which are substantially opaque, it is desirable to increase the Dp in order to ensure suitability for use in additive fabrication. In order to effectuate this, in an embodiment it is desirable to manipulate the known tendencies of an included visual effect initiator.

Thus, in an example in which a liquid radiation curable resin were substantially opaque (and thus possessed a low Dp) under standard environmental conditions (room temperature, atmospheric pressure, neutral pH, approximately zero magnetic force or electric current) with a visual effect initiator which increases in transparency when subjected to concomitant increases in electric current, it would be desirable to induce an increase in the Dp of such a resin to improve its workability in additive fabrication processes. This would be achieved by subjecting the resin to an electric current above its activation point, such that the transparency, and in turn the Dp, of the resin would be at least temporarily increased to a level such that a lower amount of exposure to actinic radiation would be required to cure a predefined layer of resin. The current would then be removed upon completion of the layer or part build, such that the desired aesthetic effects (in this case, a certain degree of opacity) could be restored and appreciated. This method would ensure that the liquid radiation curable resin could be modified to achieve maximum suitability for use in an additive fabrication process, without sacrificing the desired aesthetic qualities in a three-dimensional part cured therefrom.

In an embodiment, the method of forming a three-dimensional article via additive fabrication would incorporate liquid radiation curable resin possessing a thermochromic component having an activation temperature and a terminal activation temperature. In this non-limiting example, the thermochromic component is black below its activation temperature, and gradually transitions from black to clear from between the activation temperature to the terminal activation temperature, and becomes substantially colorless at and above the terminal activation temperature. By heating the resin—and the thermochromic component immersed therein—to at least the activation temperature, the thermochromic component would therefore necessarily impart a change in the resin's color, opacity, or both. This, in turn, would provide a concomitant increase in the resin's depth of penetration (Dp). It naturally follows from the foregoing that the Dp would increase inversely with the intensity of the black color exhibited in the resin.

In the preceding example as applied to a stereolithography process, the temperature of the vat in which the liquid radiation curable resin for additive fabrication were stored could be controlled as an alternative means to control the Dp of the resin. Thus, by simply heating the vat into which the resin were inserted, one could adjust the energy-efficiency, accuracy, and speed with which the three-dimensional parts might be built, all without modifying cure dose, scan speed, focal parameters, or programmed layer thickness.

In another embodiment, the thermochromic component transitions from a colored state of red, orange, yellow, green, blue, indigo, violet, or white, to a partially colorless state at its activation temperature, and to a substantially colorless state at its terminal activation temperature. In another embodiment, the thermochromic component transitions from an opaque state to a partially transparent state at its activation temperature, and to a substantially transparent state at its terminal activation temperature.

In another embodiment, the thermochromic component transitions from a colored state of red, orange, yellow, green, blue, indigo, violet, white, or black, to a second colored state at its activation temperature, and to a third colored state at its terminal activation temperature. The second colored state is a starting point in a transition towards another color or the same color of somewhat different intensity. The third colored state is a finishing point in the transition towards another color or the same color of somewhat different intensity.

Once a three-dimensional part has been formed from a liquid radiation curable resin via an additive fabrication according to the first aspect of the invention, it may be desirable to restore its appearance to the pre-Dp-increased visual state. Consistent with an embodiment of the method of the first aspect of the invention, this might be performed by reversing the change in the environmental condition upon the three-dimensional cured part that was originally imposed upon the liquid radiation curable resin during the part build. More specifically, a further (and opposite) change to the environmental condition would have to be imposed such that that condition were brought to below the activation point of the included visual effect initiator. This might be effectuated by, for example, an elimination of the magnetic force, pressure, or electric current originally applied to a liquid radiation curable resin.

Thus, in a non-limiting example, the liquid radiation curable composition for additive fabrication comprises a visual effect initiator which is a thermochromic component, and which exists as black at temperatures up to its activation temperature of about 20 degrees Celsius, more preferably about 30 degrees Celsius, more preferably 31 degrees Celsius. Starting from the activation temperature, the thermochromic component will begin to fade gradually from partially colorless to substantially colorless when the terminal activation temperature has been reached at 41 degrees Celsius, more preferably 40 degrees Celsius, more preferably 35 degrees Celsius. Increases in temperature beyond its terminal activation point would not yield additional changes to the visual appearance. In this example, after a three-dimensional article had been created, it would be possible to restore the original black appearance by cooling the article to a point back below the activation temperature. What had started as a black resin, and became an at least partially colorless resin (with an increased Dp) during a part build in order to improve suitability for use in an additive fabrication process, again appears black, consistent with the original aesthetic design choice.

In an embodiment, the activation temperature of the thermochromic component is from −15 degrees Celsius to about 75 degrees Celsius, more preferably from about 20 degrees Celsius to about 65 degrees Celsius, more preferably from about 30 degrees Celsius to about 43 degrees Celsius, more preferably from about 31 degrees Celsius to about 35 degrees Celsius.

In an embodiment, the difference between the activation temperature and the terminal activation temperature is from about 0 to about 50 degrees Celsius, more preferably from about 1 to about 25 degrees Celsius, more preferably from about 2 to about 10 degrees Celsius.

In certain embodiments, the visual effect initiator is non-permanent and reversible. In an embodiment, the visual effect initiator is a thermochromic component that does not possess a locking temperature; that is, the changes in color or opacity are always reversible, regardless the amount of heat applied or removed. Thus when the visual effect initiator is reversible or the thermochromic component does not possess a locking temperature, it is possible to repeatedly apply and remove heat to above and below the activation point to produce a desired, non-permanent visual effect. When incorporated into a liquid radiation curable resin, the visual effects caused by certain visual effect initiators according to the present invention continue to be able to be imparted to the three-dimensional article even after the additive fabrication process has completed.

Such reversibly color-changing characteristics are advantageous over the current state of the art, and are especially desired for certain industry applications. For example, a resin having such a thermochromic component may be employed in prototyping applications for the automotive, aerospace, or nautical industries. Engineers might fashion a three-dimensional article from such resin, and then apply it to test mechanical devices. The reversible and changeable nature of the resin would indicate relative locations of higher and lower temperature during operation, perhaps due to friction or proximity to heat generating componentry. Flaws or weaknesses in a particular design could quickly be identified in real-time, and all without the need for expensive thermal imaging equipment. Additionally, such resins could be incorporated into the fabrication of end-use components, and would provide an intrinsic indicator that a component is perhaps overheating or needs to be replaced.

Resins incorporating visual effect initiators are also advantageous in that they can be used with a hybrid curing system. A hybrid curing system is a curing system consisting of free-radical and cationic photoinitiators along with free-radical and cationic polymerizable components. When a non-hybrid system is subject to irradiation in order to form a three-dimensional article, the formed three-dimensional article possesses undesirable physical properties. Hybrid systems allow for three-dimensional articles that possess excellent mechanical properties.

The origin of the change in visual state due to the presence of a visual effect initiator can occur from changes in light absorption, light reflection, and/or light scattering with temperature. Visual effect initiators can be present in various types of compounds, and may contain microcapsules which shield a change in a pigment or dye until an activation point has been reached. In certain embodiments the visual effect initiator is a thermochromic component. In an embodiment, the thermochromic component contains a microcapsule that further includes a heat-sensitive component or components, such as pigments or dyes. In an embodiment, the component contained in the microcapsule is a leuco dye, which possesses two forms, one of which is colorless above the activation temperature or terminal activation temperature. A write-up of thermochromism in polymers can be found in Thermochromic Phenomena in Polymers, © 2008 Arno Seeboth and Detlef Lötzsch. Additional information concerning thermochromic compounds can be found in Organic Photochromic and Thermochromic Compounds, Volume 2, © 1999 John C. Crano and Robert J. Guglielmetti.

Examples of thermochromic components can be found in U.S. Pat. Nos. 7,304,008, 6,008,269, and 4,424,990, and in WO/2009/137709. Other thermochromic compounds can be found in, for instance, Japanese patent publications 2005-220201, 2007-332232, 2003-313453, 2001-242249, 10-152638, 03-076783, 03-076786, and 1522236. Examples of a commercially available thermochromic component are the YT-, OT-, MT-, RT-, GT-, ST-, BT-, VT-, and LT-series thermochromic pigments sold through Kelly Chemical Corporation, in Taipei, Taiwan. The thermochromic pigments sold through Kelly possess a particle size distribution of from 1 to 6 micrometers, and possess approximately 50 to 80% by weight of methyl stearate, from approximately 1 to 5% by weight of a melamine formaldehyde resin, from approximately 5 to 15% by weight of pH control additives, and from approximately 2 to 10% by weight of a color agent.

In an embodiment, the visual effect initiator is halochromic. Halochromic components change color based pH. Alone, such components are not effective with a hybrid curing system unless they can be appropriately contained and shielded from the acid present during cationic polymerization. If the halochromic components are not appropriately contained, for instance in an acid-impermeable microcapsule, the acid created from the cationic photoinitiating system will react with the halochromic components and cause the halochromic components to prematurely change color. In an embodiment, a non-hybrid curing system is used. In another embodiment, a hybrid curing system is used. In an embodiment, the thermochromic component does not undergo any significant visual color or transparency change in response to the acid produced during the polymerization of the liquid radiation curable resin. In an embodiment the visual effect initiator comprises an acid-impermeable microcapsule. In another embodiment the visual effect initiator comprises a microcapsule that is substantially impermeable to acid.

In an embodiment, the visual effect initiator component is a thermochromic component which also comprises a halochromic component contained within an acid-impermeable, or substantially acid-impermeable microcapsule. In such a configuration, a thermochromic component is activated upon heating to separate a pH control agent from a halochromic dye. At above an activation temperature or terminal activation temperature, the microcapsules exhibit no color, wherein upon cooling, they exhibit the specified color, for example red, orange, yellow, green, blue, indigo, violet, white, or black. In such a configuration, the color change is reversible and non-permanent.

The visual effect initiators of the present invention can be incorporated into a liquid radiation curable resin without any substantial reduction in the mechanical properties of the resin. In an embodiment, the visual effect initiator is incorporated into a liquid radiation curable resin by mixing the visual effect initiator into the liquid radiation curable resin. In an embodiment, the visual effect initiator is incorporated into a liquid radiation curable resin by mixing the liquid radiation curable resin into the visual effect initiator. In an embodiment, the visual effect initiator is incorporated into the liquid radiation curable resin along with the solvent which contains the visual effect initiator and, in another embodiment, without the solvent.

The visual effect initiator may be incorporated into the liquid radiation curable resin in any suitable amount, and may be chosen singly or in combination of one or more of the types enumerated herein. In an embodiment, the amount of the visual effect initiator is present in an amount from about 0.005 wt % to about 10 wt %. In another embodiment, the amount of visual effect initiator is present in an amount from about 0.005 wt % to about 5 wt %. In another embodiment, the amount of visual effect initiator is present in an amount from about 0.005 wt % to about 2 wt %. In another embodiment, the amount of visual effect initiator is present in an amount from about 0.005 wt % to about 1 wt %. In another embodiment, the amount of visual effect initiator is present in an amount from about 0.01 wt % to about 1 wt %. In another embodiment, the amount of visual effect initiator is present in an amount from about 0.05 wt % to about 5 wt %. In another embodiment, the amount of visual effect initiator is present in an amount from about 0.5 wt % to about 1 wt %.

In another embodiment, the amount of the thermochromic component is present in an amount from about 0.005 wt % to about 10 wt %. In another embodiment, the amount of thermochromic component is present in an amount from about 0.005 wt % to about 5 wt %. In another embodiment, the amount of thermochromic component is present in an amount from about 0.005 wt % to about 2 wt %. In another embodiment, the amount of thermochromic component is present in an amount from about 0.005 wt % to about 1 wt %. In another embodiment, the amount of thermochromic component is present in an amount from about 0.01 wt % to about 1 wt %. In another embodiment, the amount of thermochromic component is present in an amount from about 0.05 wt % to about 5 wt %. In another embodiment, the amount of thermochromic component is present in an amount from about 0.5 wt % to about 1 wt %.

In an embodiment, the visual effect initiator is incorporated into Somos® WaterClear® Ultra 10122 liquid radiation curable resin. In another embodiment, the visual effect initiator is incorporated into Somos® WaterShed® XC 11122 liquid radiation curable resin. Somos® WaterClear® Ultra 10122 and Somos® WaterShed® XC 11122 are liquid radiation curable resins manufactured by DSM Desotech, Inc. Both Somos® WaterClear® Ultra 10122 and Somos® WaterShed® XC 11122 are substantially colorless and transparent after full cure. Somos® WaterClear® Ultra 10122 comprises between 45-70 wt % of epoxies, 10-25 wt % of acrylates, 5-15 wt % of oxetane, 5-15 wt % of polyol, 1-15 wt % of photoinitiators, and 0-10 wt % of additives. Somos® WaterShed® XC 11122 comprises between 45-70 wt % of epoxies, 5-20 wt % of acrylate, 10-25 wt % of oxetane, 1-15 wt % of photoinitiators, and 0-10 wt % of additives.

In another embodiment, the visual effect initiator is incorporated into a filled resin, such as Somos® PerFORM™, NanoTool® HP, or NanoTool®. Such filled resins are typically milky white and at least partially opaque. Additionally, such filled liquid radiation curable resins for additive fabrication include suitable amounts of a cationically polymerizable component, a free-radical polymerizable component, a cationic photoinitiator, a free-radical photoinitiator, and a filler component. The filler component can include any suitable amount of inorganic filler or combination of inorganic fillers, for example, in an amount up to about 80 wt % of the resin composition, in certain embodiments from about 30 to about 80 wt % of the resin composition, and in further embodiments from about 50 to about 70 wt % of the resin composition. If the amount of the filler is too small, the water and heat resistant properties, durability, and structural rigidity of the molds made of the prepared resin composition do not increase sufficiently. On the other hand, if the amount of the filler component is too large, various problems might emerge. First, the fluidity of the prepared resin composition becomes too low, rendering it difficult or even un-workable in additive fabrication processes. Further, the ability to adjust the Dp of the resin to suitable levels is compromised by the excessive presence of light scattering and/or absorbing particles. This can also affect the time needed for radiation curing of the resin composition, causing the processing time to increase substantially.

The incorporation of visual effect initiators, such as thermochromic components, into liquid radiation curable resins for additive fabrication, also can impart desirable mechanical properties into the three-dimensional parts cured therefrom, such as a high modulus and stiffness. By practicing the method according to the first embodiment of the invention, it is possible to utilize such formulations in various prototyping applications, such for wind tunnel testing in the aerospace and auto racing industries. The friction generated by wind traversing over select surfaces would be evidenced by the portions along a three-dimensional article in which the thermochromic component is heated above its activation temperature or terminal activation temperature, allowing engineers to assess in real time areas of relative higher loading.

In another embodiment, the liquid radiation curable resin comprises at least one visual effect initiator which is a transparency modifier. A transparency modifier may also be a thermochromic component, or it may be activated by response to other changes in other environmental conditions, such as light, pressure, magnetism, pH, or electric current. The transparency modifier may operate by modifying how light passes through the three-dimensional article. This light scattering effect causes the article to become opaque or substantially opaque in certain sections. If the three-dimensional article is clear and colorless in sections where the transparency modifier is not activated, the article may appear to be white in sections where the transparency has been modified. This is because the modification to the transparency causes light to reflect back at the viewer, thus producing the white color.

In another embodiment, the amount of transparency modifier is present in an amount from about 0.005 wt % to about 5 wt %. In another embodiment, the amount of transparency modifier is present in an amount from about 0.005 wt % to about 3 wt %. In another embodiment, the amount of transparency modifier is present in an amount from about 0.005 wt % to about 2 wt %. In another embodiment, the amount of transparency modifier is present in an amount from about 0.005 wt % to about 1 wt %. In another embodiment, the amount of transparency modifier is present in an amount from about 0.01 wt % to about 5 wt %. In another embodiment, the amount of transparency modifier is present in an amount from about 0.05 wt % to about 5 wt %. In another embodiment, the amount of transparency modifier is present in an amount from about 0.01 wt % to about 2 wt %.

In an embodiment, the transparency modifier is incorporated into a substantially clear liquid radiation curable resin. In another embodiment, the transparency modifier is incorporated into a substantially clear and colorless liquid radiation curable resin. In another embodiment, more than one visual effect initiator is incorporated into the liquid radiation curable resin composition. In one embodiment, each of the more than one visual effect initiators has the same activation and/or locking temperature.

In accordance with an embodiment of the invention, the liquid radiation curable resin comprises a visual effect initiator, a free radical polymerizable component, and a photoinitiating system capable of initiating free radical polymerization. In another embodiment, the liquid radiation curable resin comprises a visual effect initiator, a cationic polymerizable component, and a photoinitiating system capable of initiating cationic polymerization. In a further embodiment, the liquid radiation curable resin comprises a visual effect initiator, a free radical polymerizable component, a photoinitiating system capable of initiating free radical polymerization, a cationic polymerizable component, and a photoinitiating system capable of initiating cationic polymerization.

In accordance with an embodiment of the invention, the liquid radiation curable resin of the invention may comprise at least one free-radical polymerizable component, that is, a component which undergoes polymerization initiated by free radicals. The free-radical polymerizable components are monomers, oligomers, and/or polymers; they are monofunctional or polyfunctional materials, i.e., have 1, 2, 3, 4, 5, 6, 7, 8, 9, 10, 20, 30, 40, 50, 100, or more functional groups that can polymerize by free radical initiation, may contain aliphatic, aromatic, cycloaliphatic, arylaliphatic, heterocyclic moiety(ies), or any combination thereof. Examples of polyfunctional materials include dendritic polymers such as dendrimers, linear dendritic polymers, dendrigraft polymers, hyperbranched polymers, star branched polymers, and hypergraft polymers; see US 2009/0093564 A1. The dendritic polymers may contain one type of polymerizable functional group or different types of polymerizable functional groups, for example, acrylates and methacrylate functions.

Examples of free-radical polymerizable components include acrylates and methacrylates such as isobornyl (meth)acrylate, bornyl (meth)acrylate, tricyclodecanyl (meth)acrylate, dicyclopentanyl (meth)acrylate, dicyclopentenyl (meth)acrylate, cyclohexyl (meth)acrylate, benzyl (meth)acrylate, 4-butylcyclohexyl (meth)acrylate, acryloyl morpholine, (meth)acrylic acid, 2-hydroxyethyl (meth)acrylate, 2-hydroxypropyl (meth)acrylate, 2-hydroxybutyl (meth)acrylate, methyl (meth)acrylate, ethyl (meth)acrylate, propyl (meth)acrylate, isopropyl (meth)acrylate, butyl (meth)acrylate, amyl (meth)acrylate, isobutyl (meth)acrylate, t-butyl (meth)acrylate, pentyl (meth)acrylate, caprolactone acrylate, isoamyl (meth)acrylate, hexyl (meth)acrylate, heptyl (meth)acrylate, octyl (meth)acrylate, isooctyl (meth)acrylate, 2-ethylhexyl (meth)acrylate, nonyl (meth)acrylate, decyl (meth)acrylate, isodecyl (meth)acrylate, tridecyl (meth)acrylate, undecyl (meth)acrylate, lauryl (meth)acrylate, stearyl (meth)acrylate, isostearyl (meth)acrylate, tetrahydrofurfuryl (meth)acrylate, butoxyethyl (meth)acrylate, ethoxydiethylene glycol (meth)acrylate, benzyl (meth)acrylate, phenoxyethyl (meth)acrylate, polyethylene glycol mono(meth)acrylate, polypropylene glycol mono(meth)acrylate, methoxyethylene glycol (meth)acrylate, ethoxyethyl (meth)acrylate, methoxypolyethylene glycol (meth)acrylate, methoxypolypropylene glycol (meth)acrylate, diacetone (meth)acrylamide, beta-carboxyethyl (meth)acrylate, phthalic acid (meth)acrylate, dimethylaminoethyl (meth)acrylate, diethylaminoethyl (meth)acrylate, butylcarbamylethyl (meth)acrylate, n-isopropyl (meth)acrylamide fluorinated (meth)acrylate, 7-amino-3,7-dimethyloctyl (meth)acrylate.

Examples of polyfunctional free-radical polymerizable components include those with (meth)acryloyl groups such as trimethylolpropane tri(meth)acrylate, pentaerythritol (meth)acrylate, ethylene glycol di(meth)acrylate, bisphenol A diglycidyl ether di(meth)acrylate, dicyclopentadiene dimethanol di(meth)acrylate, [2-[1,1-dimethyl-2-[(1-oxoallyl)oxy]ethyl]-5-ethyl-1,3-dioxan-5-yl]methyl acrylate; 3,9-bis(1,1-dimethyl-2-hydroxyethyl)-2,4,8,10-tetraoxaspiro[5.5]undecane di(meth)acrylate; dipentaerythritol monohydroxypenta(meth)acrylate, propoxylated trimethylolpropane tri(meth)acrylate, propoxylated neopentyl glycol di(meth)acrylate, tetraethylene glycol di(meth)acrylate, polyethylene glycol di(meth)acrylate, 1,4-butanediol di(meth)acrylate, 1,6-hexanediol di(meth)acrylate, neopentyl glycol di(meth)acrylate, polybutanediol di(meth)acrylate, tripropyleneglycol di(meth)acrylate, glycerol tri(meth)acrylate, phosphoric acid mono- and di(meth)acrylates, C₇-C₂₀ alkyl di(meth)acrylates, tris(2-hydroxyethyl)isocyanurate tri(meth)acrylate, tris(2-hydroxyethyl)isocyanurate di(meth)acrylate, pentaerythritol tri(meth)acrylate, pentaerythritol tetra(meth)acrylate, dipentaerythritol hexa(meth)crylate, tricyclodecane diyl dimethyl di(meth)acrylate and alkoxylated versions (e.g., ethoxylated and/or propoxylated) of any of the preceding monomers, and also di(meth)acrylate of a diol which is an ethylene oxide or propylene oxide adduct to bisphenol A, di(meth)acrylate of a diol which is an ethylene oxide or propylene oxide adduct to hydrogenated bisphenol A, epoxy (meth)acrylate which is a (meth)acrylate adduct to bisphenol A of diglycidyl ether, diacrylate of polyoxyalkylated bisphenol A, and triethylene glycol divinyl ether, and adducts of hydroxyethyl acrylate.

In accordance with an embodiment, the polyfunctional (meth)acrylates of the polyfunctional component may include all methacryloyl groups, all acryloyl groups, or any combination of methacryloyl and acryloyl groups. In an embodiment, the free-radical polymerizable component is selected from the group consisting of bisphenol A diglycidyl ether di(meth)acrylate, ethoxylated or propoxylated bisphenol A or bisphenol F di(meth)acrylate, dicyclopentadiene dimethanol di(meth)acrylate, [2-[1,1-dimethyl-2-[(1-oxoallyl)oxy]ethyl]-5-ethyl-1,3-dioxan-5-yl]methyl acrylate, dipentaerythritol monohydroxypenta(meth)acrylate, dipentaerythritol hexa(meth)crylate, propoxylated trimethylolpropane tri(meth)acrylate, and propoxylated neopentyl glycol di(meth)acrylate, and any combination thereof.

In another embodiment, the free-radical polymerizable component is selected from the group consisting of bisphenol A diglycidyl ether diacrylate, dicyclopentadiene dimethanol diacrylate, [2-[1,1-dimethyl-2-[(1-oxoallyl)oxy]ethyl]-5-ethyl-1,3-dioxan-5-yl]methyl acrylate, dipentaerythritol monohydroxypentaacrylate, propoxylated trimethylolpropane triacrylate, and propoxylated neopentyl glycol diacrylate, and any combination thereof.

In specific embodiments, the liquid radiation curable resin compositions of the invention include one or more of bisphenol A diglycidyl ether di(meth)acrylate, dicyclopentadiene dimethanol di(meth)acrylate, dipentaerythritol monohydroxypenta(meth)acrylate, propoxylated trimethylolpropane tri(meth)acrylate, and/or propoxylated neopentyl glycol di(meth)acrylate, and more specifically one or more of bisphenol A diglycidyl ether diacrylate, dicyclopentadiene dimethanol diacrylate, dipentaerythritol monohydroxypentaacrylate, propoxylated trimethylolpropane triacrylate, and/or propoxylated neopentyl glycol diacrylate.

The liquid radiation curable resin composition can include any suitable amount of the free-radical polymerizable component, for example, in certain embodiments, in an amount up to about 95% by weight of the composition, in certain embodiments, up to about 50% by weight of the composition, and in further embodiments from about 5% to about 25% by weight of the composition.

In all embodiments, the liquid radiation curable resin composition of the present invention includes a photoinitiating system. The photoinitiating system can be a free-radical photoinitiator or a cationic photoinitiator or a photoinitiator that contains both free-radical initiating function and cationic initiating functions on the same molecule. The photoinitiator is a compound that chemically changes due to the action of light or the synergy between the action of light and the electronic excitation of a sensitizing dye to produce at least one of a radical, an acid, and a base.

Typically, free radical photoinitiators are divided into those that form radicals by cleavage, known as “Norrish Type I” and those that form radicals by hydrogen abstraction, known as “Norrish type II”. The Norrish type II photoinitiators require a hydrogen donor, which serves as the free radical source. As the initiation is based on a bimolecular reaction, the Norrish type II photoinitiators are generally slower than Norrish type I photoinitiators which are based on the unimolecular formation of radicals. On the other hand, Norrish type II photoinitiators possess better optical absorption properties in the near-UV spectroscopic region. Photolysis of aromatic ketones, such as benzophenone, thioxanthones, benzil, and quinones, in the presence of hydrogen donors, such as alcohols, amines, or thiols leads to the formation of a radical produced from the carbonyl compound (ketyl-type radical) and another radical derived from the hydrogen donor. The photopolymerization of vinyl monomers is usually initiated by the radicals produced from the hydrogen donor. The ketyl radicals are usually not reactive toward vinyl monomers because of the steric hindrance and the delocalization of an unpaired electron.

To successfully formulate a liquid radiation curable resin composition, it is necessary to review the wavelength sensitivity of the photoinitiator(s) present in the composition to determine if they will be activated by the method and wavelength of irradiation chosen to cure the composition.

In accordance with an embodiment, the liquid radiation curable resin composition includes at least one free radical photoinitiator, e.g., those selected from the group consisting of benzoylphosphine oxides, aryl ketones, benzophenones, hydroxylated ketones, 1-hydroxyphenyl ketones, ketals, metallocenes, and any combination thereof.

In an embodiment, the liquid radiation curable resin composition includes at least one free-radical photoinitiator selected from the group consisting of 2,4,6-trimethylbenzoyl diphenylphosphine oxide and 2,4,6-trimethylbenzoyl phenyl, ethoxy phosphine oxide, bis(2,4,6-trimethylbenzoyl)-phenylphosphineoxide, 2-methyl-1-[4-(methylthio)phenyl]-2-morpholinopropanone-1, 2-benzyl-2-(dimethylamino)-1-[4-(4-morpholinyl) phenyl]-1-butanone, 2-dimethylamino-2-(4-methyl-benzyl)-1-(4-morpholin-4-yl-phenyl)-butan-1-one, 4-benzoyl-4′-methyl diphenyl sulphide, 4,4′-bis(diethylamino) benzophenone, and 4,4′-bis(N,N′-dimethylamino) benzophenone (Michler's ketone), benzophenone, 4-methyl benzophenone, 2,4,6-trimethyl benzophenone, dimethoxybenzophenone, 1-hydroxycyclohexyl phenyl ketone, phenyl (1-hydroxyisopropyl)ketone, 2-hydroxy-1-[4-(2-hydroxyethoxy) phenyl]-2-methyl-1-propanone, 4-isopropylphenyl(1-hydroxyisopropyl)ketone, oligo-[2-hydroxy-2-methyl-1-[4-(1-methylvinyl)phenyl]propanone], camphorquinone, 4,4′-bis(diethylamino) benzophenone, benzil dimethyl ketal, bis(eta 5-2-4-cyclopentadien-1-yl) bis[2,6-difluoro-3-(1H-pyrrol-1-yl) phenyl] titanium, and any combination thereof.

For light sources emitting in the 300-475 nm wavelength range, especially those emitting at 365 nm, 390 nm, or 395 nm, examples of suitable free-radical photoinitiators absorbing in this area include: benzoylphosphine oxides, such as, for example, 2,4,6-trimethylbenzoyl diphenylphosphine oxide (Lucirin TPO from BASF) and 2,4,6-trimethylbenzoyl phenyl, ethoxy phosphine oxide (Lucirin TPO-L from BASF), bis(2,4,6-trimethylbenzoyl)-phenylphosphineoxide (Irgacure 819 or BAPO from Ciba), 2-methyl-1-[4-(methylthio)phenyl]-2-morpholinopropanone-1 (Irgacure 907 from Ciba), 2-benzyl-2-(dimethylamino)-1-[4-(4-morpholinyl) phenyl]-1-butanone (Irgacure 369 from Ciba), 2-dimethylamino-2-(4-methyl-benzyl)-1-(4-morpholin-4-yl-phenyl)-butan-1-one (Irgacure 379 from Ciba), 4-benzoyl-4′-methyl diphenyl sulphide (Chivacure BMS from Chitec), 4,4′-bis(diethylamino) benzophenone (Chivacure EMK from Chitec), and 4,4′-bis(N,N′-dimethylamino) benzophenone (Michler's ketone). Also suitable are mixtures thereof.

Additionally, photosensitizers are useful in conjunction with photoinitiators in effecting cure with light sources emitting in this wavelength range. Examples of suitable photosensitizers include: anthraquinones, such as 2-methylanthraquinone, 2-ethylanthraquinone, 2-tertbutylanthraquinone, 1-chloroanthraquinone, and 2-amylanthraquinone, thioxanthones and xanthones, such as isopropyl thioxanthone, 2-chlorothioxanthone, 2,4-diethylthioxanthone, and 1-chloro-4-propoxythioxanthone, methyl benzoyl formate (Darocur MBF from Ciba), methyl-2-benzoyl benzoate (Chivacure OMB from Chitec), 4-benzoyl-4′-methyl diphenyl sulphide (Chivacure BMS from Chitec), 4,4′-bis(diethylamino) benzophenone (Chivacure EMK from Chitec).

It is possible for UV light sources to be designed to emit light at shorter wavelengths. For light sources emitting at wavelengths from between about 100 and about 300 nm, it is desirable to employ a photosensitizer with a photoinitiator. When photosensitizers, such as those previously listed are present in the formulation, other photoinitiators absorbing at shorter wavelengths can be used. Examples of such photoinitiators include: benzophenones, such as benzophenone, 4-methyl benzophenone, 2,4,6-trimethyl benzophenone, and dimethoxybenzophenone, and, 1-hydroxyphenyl ketones, such as 1-hydroxycyclohexyl phenyl ketone, phenyl (1-hydroxyisopropyl)ketone, 2-hydroxy-1-[4-(2-hroxyethoxy) phenyl]-2-methyl-1-propanone, and 4-isopropylphenyl(1-hydroxyisopropyl)ketone, benzil dimethyl ketal, and oligo-[2-hydroxy-2-methyl-1-[4-(1-methylvinyl)phenyl]propanone] (Esacure KIP 150 from Lamberti).

Light sources can also be designed to emit visible light. For light sources emitting light at wavelengths from about 475 nm to about 900 nm, examples of suitable free radical photoinitiators include: camphorquinone, 4,4′-bis(diethylamino) benzophenone (Chivacure EMK from Chitec), 4,4′-bis(N,N′-dimethylamino) benzophenone (Michler's ketone), bis(2,4,6-trimethylbenzoyl)-phenylphosphineoxide (Irgacure 819 or BAPO from Ciba), metallocenes such as bis (eta 5-2-4-cyclopentadien-1-yl) bis [2,6-difluoro-3-(1H-pyrrol-1-yl) phenyl] titanium (Irgacure 784 from Ciba), and the visible light photoinitiators from Spectra Group Limited, Inc. such as H-Nu 470, H-Nu-535, H-Nu-635, H-Nu-Blue-640, and H-Nu-Blue-660.

The liquid radiation curable resin composition can include any suitable amount of the free-radical photoinitiator, for example, in certain embodiments, in an amount up to about 15% by weight of the composition, in certain embodiments, up to about 10% by weight of the composition, and in further embodiments from about 1% to about 5% by weight of the composition. In other embodiments, the amount of free-radical photoinitiator is present in an amount of from about 1 wt % to about 8 wt % of the total composition, more preferably from about 1 wt % to about 6 wt % of the total composition.

In accordance with an embodiment, liquid radiation curable resin compositions of the invention comprise at least one cationically polymerizable component, that is, a component which undergoes polymerization initiated by cations or in the presence of acid generators. The cationically polymerizable components may be monomers, oligomers, and/or polymers, and may contain aliphatic, aromatic, cycloaliphatic, arylaliphatic, heterocyclic moiety(ies), and any combination thereof. Suitable cyclic ether compounds can comprise cyclic ether groups as side groups or groups that form part of an alicyclic or heterocyclic ring system.

The cationic polymerizable component is selected from the group consisting of cyclic ether compounds, cyclic acetal compounds, cyclic thioethers compounds, spiro-orthoester compounds, cyclic lactone compounds, and vinyl ether compounds, and any combination thereof.

Examples of cationically polymerizable components include cyclic ether compounds such as epoxy compounds and oxetanes, cyclic lactone compounds, cyclic acetal compounds, cyclic thioether compounds, spiro orthoester compounds, and vinylether compounds. Specific examples of cationically polymerizable components include bisphenol A diglycidyl ether, bisphenol F diglycidyl ether, bisphenol S diglycidyl ether, brominated bisphenol A diglycidyl ether, brominated bisphenol F diglycidyl ether, brominated bisphenol S diglycidyl ether, epoxy novolac resins, hydrogenated bisphenol A diglycidyl ether, hydrogenated bisphenol F diglycidyl ether, hydrogenated bisphenol S diglycidyl ether, 3,4-epoxycyclohexylmethyl-3′,4′-epoxycyclohexanecarboxylate, 2-(3,4-epoxycyclohexyl-5,5-spiro-3,4-epoxy)-cyclohexane-1,4-dioxane, bis(3,4-epoxycyclohexylmethyl)adipate, vinylcyclohexene oxide, 4-vinylepoxycyclohexane, vinylcyclohexene dioxide, limonene oxide, limonene dioxide, bis(3,4-epoxy-6-methylcyclohexylmethyl)adipate, 3,4-epoxy-6-methylcyclohexyl-3′,4′-epoxy-6′-methylcyclohexanecarboxylate, ε-caprolactone-modified 3,4-epoxycyclohexylmethyl-3′,4′-epoxycyclohexane carboxylates, trimethylcaprolactone-modified 3,4-epoxycyclohexylmethyl-3′,4′-epoxycyclohexane carboxylates, β-methyl-δ-valerolactone-modified 3,4-epoxycyclohexcylmethyl-3′,4′-epoxycyclohexane carboxylates, methylenebis(3,4-epoxycyclohexane), bicyclohexyl-3,3′-epoxide, bis(3,4-epoxycyclohexyl) with a linkage of —O—, —S—, —SO—, —SO₂—, —C(CH₃)₂—, —CBr₂—, —C(CBr₃)₂—, —C(CF₃)₂—, —C(CCl₃)₂—, or —CH(C₆H₅)—, dicyclopentadiene diepoxide, di(3,4-epoxycyclohexylmethyl) ether of ethylene glycol, ethylenebis(3,4-epoxycyclohexanecarboxylate), epoxyhexahydrodioctylphthalate, epoxyhexahydro-di-2-ethylhexyl phthalate, 1,4-butanediol diglycidyl ether, 1,6-hexanediol diglycidyl ether, neopentylglycol diglycidyl ether, glycerol triglycidyl ether, trimethylolpropane triglycidyl ether, polyethylene glycol diglycidyl ether, polypropylene glycol diglycidyl ether, polyglycidyl ethers of polyether polyol obtained by the addition of one or more alkylene oxides to aliphatic polyhydric alcohols such as ethylene glycol, propylene glycol, and glycerol, diglycidyl esters of aliphatic long-chain dibasic acids, monoglycidyl ethers of aliphatic higher alcohols, monoglycidyl ethers of phenol, cresol, butyl phenol, or polyether alcohols obtained by the addition of alkylene oxide to these compounds, glycidyl esters of higher fatty acids, epoxidated soybean oil, epoxybutylstearic acid, epoxyoctylstearic acid, epoxidated linseed oil, epoxidated polybutadiene, 1,4-bis[(3-ethyl-3-oxetanylmethoxy)methyl]benzene, 3-ethyl-3-hydroxymethyloxetane, 3-ethyl-3-(3-hydroxypropyl)oxymethyloxetane, 3-ethyl-3-(4-hydroxybutyl)oxymethyloxetane, 3-ethyl-3-(5-hydroxypentyl)oxymethyloxetane, 3-ethyl-3-phenoxymethyloxetane, bis((1-ethyl(3-oxetanyl))methyl)ether, 3-ethyl-3-((2-ethylhexyloxy)methyl)oxetane, 3-ethyl-((triethoxysilylpropoxymethyl)oxetane, 3-(meth)-allyloxymethyl-3-ethyloxetane, (3-ethyl-3-oxetanylmethoxy)methylbenzene, 4-fluoro-[1-(3-ethyl-3-oxetanylmethoxy)methyl]benzene, 4-methoxy-[1-(3-ethyl-3-oxetanylmethoxy)methyl]-benzene, [1-(3-ethyl-3-oxetanylmethoxy)ethyl]phenyl ether, isobutoxymethyl(3-ethyl-3-oxetanylmethyl)ether, 2-ethylhexyl(3-ethyl-3-oxetanylmethyl)ether, ethyldiethylene glycol(3-ethyl-3-oxetanylmethyl)ether, dicyclopentadiene (3-ethyl-3-oxetanylmethyl)ether, dicyclopentenyloxyethyl(3-ethyl-3-oxetanylmethyl)ether, dicyclopentenyl(3-ethyl-3-oxetanylmethyl)ether, tetrahydrofurfuyl(3-ethyl-3-oxetanylmethyl)ether, 2-hydroxyethyl(3-ethyl-3-oxetanylmethyl)ether, 2-hydroxypropyl(3-ethyl-3-oxetanylmethyl)ether, and any combination thereof. Examples of polyfunctional materials that are cationically polymerizable include dendritic polymers such as dendrimers, linear dendritic polymers, dendrigraft polymers, hyperbranched polymers, star branched polymers, and hypergraft polymers with epoxy or oxetane functional groups. The dendritic polymers may contain one type of polymerizable functional group or different types of polymerizable functional groups, for example, epoxy and oxetane functions.

In embodiments of the invention, the cationic polymerizable component is at least one selected from the group consisting of a cycloaliphatic epoxy and an oxetane. In a specific embodiment, the cationic polymerizable component is an oxetane, for example, an oxetane containing 2 or more than 2 oxetane groups. In another specific embodiment, the cationic polymerizable component is a cycloaliphatic epoxy, for example, a cycloaliphatic epoxy with 2 or more than 2 epoxy groups.

In an embodiment, the epoxide is 3,4-epoxycyclohexylmethyl-3′,4-epoxycyclohexanecarboxylate (available as CELLOXIDE™ 2021P from Daicel Chemical, or as CYRACURE™ UVR-6105 from Dow Chemical), hydrogenated bisphenol A-epichlorohydrin based epoxy resin (available as EPONEX™ 1510 from Hexion), 1,4-cyclohexanedimethanol diglycidyl ether (available as HELOXY™ 107 from Hexion), a mixture of dicyclohexyl diepoxide and nanosilica (available as NANOPDX™), and any combination thereof.

The above-mentioned cationically polymerizable compounds can be used singly or in combination of two or more thereof.

The liquid radiation curable resin composition can include any suitable amount of the cationic polymerizable component, for example, in certain embodiments, in an amount an amount up to about 95% by weight of the composition, in certain embodiments, up to about 50% by weight of the composition, and in further embodiments from about 5% to about 25% by weight of the composition. In other embodiments the amount of cationically polymerizable components if from about 10 wt % to about 80 wt % of the total composition.

In accordance with an embodiment, the polymerizable component of the liquid radiation curable resin composition is polymerizable by both free-radical polymerization and cationic polymerization. An example of such a polymerizable component is a vinyloxy compound, for example, one selected from the group consisting of bis(4-vinyloxybutyl)isophthalate, tris(4-vinyloxybutyl) trimellitate, and combinations thereof.

In accordance with an embodiment, the liquid radiation curable resin composition includes a photoinitiating system that is a photoinitiator having both cationic initiating function and free radical initiating function. In accordance with an embodiment, the liquid radiation curable resin composition includes a cationic photoinitiator. The cationic photoinitiator generates photoacids upon irradiation of light. They generate Brönsted or Lewis acids upon irradiation.

The cationic photoinitiator triaryl sulfonium tetrakis(pentafluorophenyl) borate is available from Bayer/Ciba. Triaryl sulfonium tetrakis(pentafluorophenyl) borate can be used either as the only cationic photoinitiator present in the photocurable composition or in combination with other cationic photoinitiators. In an embodiment, triaryl sulfonium tetrakis(pentafluorophenyl) borate is used in combination with sulfonium antimonate type photoinitiators.

In accordance with an embodiment, the liquid radiation curable resin composition includes a cationic photoinitiator. The cationic photoinitiator initiates cationic ring-opening polymerization upon irradiation of light.

In an embodiment, any suitable cationic photoinitiator can be used, for example, those with cations selected from the group consisting of onium salts, halonium salts, iodosyl salts, selenium salts, sulfonium salts, sulfoxonium salts, diazonium salts, metallocene salts, isoquinolinium salts, phosphonium salts, arsonium salts, tropylium salts, dialkylphenacylsulfonium salts, thiopyrilium salts, diaryl iodonium salts, triaryl sulfonium salts, ferrocenes, di(cyclopentadienyliron)arene salt compounds, and pyridinium salts, and any combination thereof.

In another embodiment, the cation of the cationic photoinitiator is selected from the group consisting of aromatic diazonium salts, aromatic sulfonium salts, aromatic iodonium salts, metallocene based compounds, aromatic phosphonium salts, and any combination thereof. In another embodiment, the cation is a polymeric sulfonium salt, such as in U.S. Pat. No. 5,380,923 or U.S. Pat. No. 5,047,568, or other aromatic heteroatom-containing cations and naphthyl-sulfonium salts such as in U.S. Pat. No. 7,611,817, U.S. Pat. No. 7,230,122, US2011/0039205, US2009/0182172, U.S. Pat. No. 7,678,528, EP2308865, WO2010046240, or EP2218715. In another embodiment, the cationic photoinitiator is selected from the group consisting of triarylsulfonium salts, diaryliodonium salts, and metallocene based compounds, and any combination thereof. Onium salts, e.g., iodonium salts and sulfonium salts, and ferrocenium salts, have the advantage that they are generally more thermally stable.

In a particular embodiment, the cationic photoinitiator has an anion selected from the group consisting of BF₄⁻, AsF₆⁻, SbF₆⁻, PF₆⁻, [B(CF₃)₄]⁻, B(C₆F₅)₄⁻, B[C₆H₃-3,5(CF₃)₂]₄⁻, B(C₆H₄CF₃)₄⁻, B(C₆H₃F₂)₄⁻, B[C₆F₄-4(CF₃)]₄⁻, Ga(C₆F₅)₄⁻, [(C₆F₅)₃B-C₃H₃N₂-B(C₆F₅)₃]⁻, [(C₆F₅)₃B-NH₂-B(C₆F₅)₃]⁻, tetrakis(3,5-difluoro-4-alkyloxyphenyl)borate, tetrakis(2,3,5,6-tetrafluoro-4-alkyloxyphenyl)borate, perfluoroalkylsulfonates, tris[(perfluoroalkyl)sulfonyl]methides, bis[(perfluoroalkyl)sulfonyl]imides, perfluoroalkylphosphates, tris(perfluoroalkyl)trifluorophosphates, bis(perfluoroalkyl)tetrafluorophosphates, tris(pentafluoroethyl)trifluorophosphates, and (CH₆B₁₁Br₆)⁻, (CH₆B₁₁Cl₆)⁻ and other halogenated carborane anions.

A survey of other onium salt initiators and/or metallocene salts can be found in “UV Curing, Science and Technology”, (Editor S. P. Pappas, Technology Marketing Corp., 642 Westover Road, Stamford, Conn., U.S.A.) or “Chemistry & Technology of UV & EB Formulation for Coatings, Inks & Paints”, Vol. 3 (edited by P. K. T. Oldring).

In an embodiment, the cationic photoinitiator has a cation selected from the group consisting of aromatic sulfonium salts, aromatic iodonium salts, and metallocene based compounds with at least an anion selected from the group consisting of SbF₆⁻, PF₆⁻, B(C₆F₅)₄⁻, [B(CF₃)₄]⁻, tetrakis(3,5-difluoro-4-methoxyphenyl)borate, perfluoroalkylsulfonates, perfluoroalkylphosphates, tris[(perfluoroalkyl)sulfonyl]methides, and [(C₂F₅)₃PF₃]⁻.

Examples of cationic photoinitiators useful for curing at 300-475 nm, particularly at 365 nm UV light, without a sensitizer include 4-[4-(3-chlorobenzoyl)phenylthio]phenylbis(4-fluorophenyl)sulfonium hexafluoroantimonate, 4-[4-(3-chlorobenzoyl)phenylthio]phenylbis(4-fluorophenyl)sulfonium tetrakis(pentafluorophenyl)borate, 4-[4-(3-chlorobenzoyl)phenylthio]phenylbis(4-fluorophenyl)sulfonium tetrakis(3,5-difluoro-4-methyloxyphenyl)borate, 4-[4-(3-chlorobenzoyl)phenylthio]phenylbis(4-fluorophenyl)sulfonium tetrakis(2,3,5,6-tetrafluoro-4-methyloxyphenyl)borate, tris(4-(4-acetylphenyl)thiophenyl)sulfonium tetrakis(pentafluorophenyl)borate (Irgacure® PAG 290 from BASF), tris(4-(4-acetylphenyl)thiophenyl)sulfonium tris[(trifluoromethyl)sulfonyl]methide (Irgacure® GSID 26-1 from BASF), tris(4-(4-acetylphenyl)thiophenyl)sulfonium hexafluorophosphate (Irgacure® 270 from BASF), and HS-1 available from San-Apro Ltd.

Preferred cationic photoinitiators include, either alone or in a mixture: bis[4-diphenylsulfoniumphenyl]sulfide bishexafluoroantimonate; thiophenoxyphenylsulfonium hexafluoroantimonate (available as Chivacure 1176 from Chitec), tris(4-(4-acetylphenyl)thiophenyl)sulfonium tetrakis(pentafluorophenyl)borate (Irgacure® PAG 290 from BASF), tris(4-(4-acetylphenyl)thiophenyl)sulfonium tris[(trifluoromethyl)sulfonyl]methide (Irgacure® GSID 26-1 from BASF), and tris(4-(4-acetylphenyl)thiophenyl)sulfonium hexafluorophosphate (Irgacure® 270 from BASF), [4-(1-methylethyl)phenyl](4-methylphenyl) iodonium tetrakis(pentafluorophenyl)borate (available as Rhodorsil 2074 from Rhodia), 4-[4-(2-chlorobenzoyl)phenylthio]phenylbis(4-fluorophenyl)sulfonium hexafluoroantimonate (as SP-172 from Adeka), SP-300 from Adeka, and aromatic sulfonium salts with anions of (PF₆₋ₘ(CₙF₂ₙ₋₁)ₘ)⁻ where m is an integer from 1 to 5, and n is an integer from 1 to 4 (available as CPI-200K or CPI-200S, which are monovalent sulfonium salts from San-Apro Ltd., TK-1 available from San-Apro Ltd., or HS-1 available from San-Apro Ltd.).

The liquid radiation curable resin composition can include any suitable amount of the cationic photoinitiator, for example, in certain embodiments, in an amount up to about 10% by weight of the composition, in certain embodiments, up to about 5% by weight of the composition, and in further embodiments from about 0.1% to about 5% by weight of the composition. In a further embodiment, the amount of cationic photoinitiator is from about 0.2 wt % to about 4 wt % of the total composition, and in other embodiments from about 0.5 wt % to about 3 wt %. In an embodiment, the above ranges are particularly suitable for use with epoxy monomers.

In some embodiments it is desirable for the liquid radiation curable resin composition to include a photosensitizer. The term “photosensitizer” is used to refer to any substance that either increases the rate of photoinitiated polymerization or shifts the wavelength at which polymerization occurs; see textbook by G. Odian, Principles of Polymerization, 3^{rd} Ed., 1991, page 222. Examples of photosensitizers include those selected from the group consisting of methanones, xanthenones, pyrenemethanols, anthracenes, pyrene, perylene, quinones, xanthones, thioxanthones, benzoyl esters, benzophenones, and any combination thereof. Particular examples of photosensitizers include those selected from the group consisting of [4-[(4-methylphenyl)thio]phenyl]phenyl-methanone, isopropyl-9H-thioxanthen-9-one, 1-pyrenemethanol, 9-(hydroxymethyl)anthracene, 9,10-diethoxyanthracene, 9,10-dimethoxyanthracene, 9,10-dipropoxyanthracene, 9,10-dibutyloxyanthracene, 9-anthracenemethanol acetate, 2-ethyl-9,10-dimethoxyanthracene, 2-methyl-9,10-dimethoxyanthracene, 2-t-butyl-9,10-dimethoxyanthracene, 2-ethyl-9,10-diethoxyanthracene and 2-methyl-9,10-diethoxyanthracene, anthracene, anthraquinones, 2-methylanthraquinone, 2-ethylanthraquinone, 2-tertbutylanthraquinone, 1-chloroanthraquinone, 2-amylanthraquinone, thioxanthones and xanthones, isopropyl thioxanthone, 2-chlorothioxanthone, 2,4-diethylthioxanthone, 1-chloro-4-propoxythioxanthone, methyl benzoyl formate, methyl-2-benzoyl benzoate, 4-benzoyl-4′-methyl diphenyl sulphide, 4,4′-bis(diethylamino) benzophenone, and any combination thereof.

Additionally, photosensitizers are useful in combination with photoinitiators in effecting cure with light sources emitting in the wavelength range of 300-475 nm. Examples of suitable photo sensitizers include: anthraquinones, such as 2-methylanthraquinone, 2-ethylanthraquinone, 2-tertbutylanthraquinone, 1-chloroanthraquinone, and 2-amylanthraquinone, thioxanthones and xanthones, such as isopropyl thioxanthone, 2-chlorothioxanthone, 2,4-diethylthioxanthone, and 1-chloro-4-propoxythioxanthone, methyl benzoyl formate (Darocur MBF from Ciba), methyl-2-benzoyl benzoate (Chivacure OMB from Chitec), 4-benzoyl-4′-methyl diphenyl sulphide (Chivacure BMS from Chitec), 4,4′-bis(diethylamino) benzophenone (Chivacure EMK from Chitec).

In an embodiment, the photosensitizer is a fluorone, e.g., 5,7-diiodo-3-butoxy-6-fluorone, 5,7-diiodo-3-hydroxy-6-fluorone, 9-cyano-5,7-diiodo-3-hydroxy-6-fluorone, or a photosensitizer is

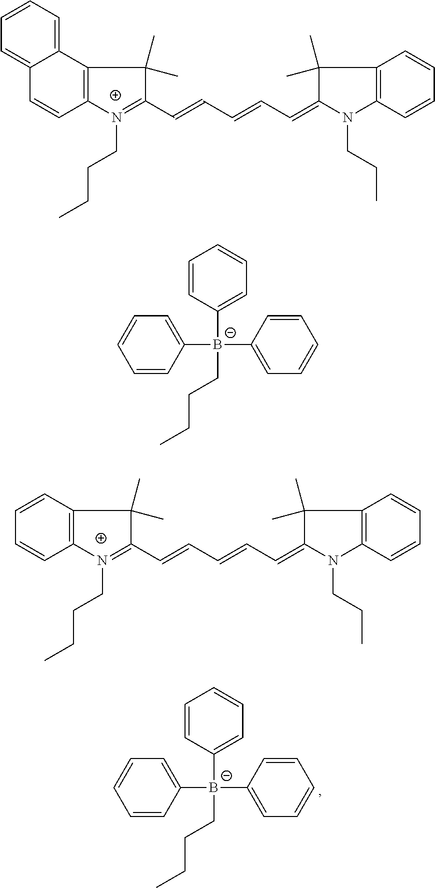

and any combination thereof.

The liquid radiation curable resin composition can include any suitable amount of the photosensitizer, for example, in certain embodiments, in an amount up to about 10% by weight of the composition, in certain embodiments, up to about 5% by weight of the composition, and in further embodiments from about 0.05% to about 2% by weight of the composition.

When photosensitizers are employed, other photoinitiators absorbing at shorter wavelengths can be used. Examples of such photoinitiators include: benzophenones, such as benzophenone, 4-methyl benzophenone, 2,4,6-trimethyl benzophenone, and dimethoxybenzophenone, and 1-hydroxyphenyl ketones, such as 1-hydroxycyclohexyl phenyl ketone, phenyl (1-hydroxyisopropyl)ketone, 2-hydroxy-1-[4-(2-hydroxyethoxy) phenyl]-2-methyl-1-propanone, and 4-isopropylphenyl(1-hydroxyisopropyl)ketone, benzil dimethyl ketal, and oligo-[2-hydroxy-2-methyl-1-[4-(1-methylvinyl)phenyl]propanone] (Esacure KIP 150 from Lamberti). These photoinitiators when used in combination with a photosensitizer are suitable for use with light sources emitting at wavelengths from about 100 nm to about 300 nm.

Light sources that emit visible light are also known. For light sources emitting light at wavelengths greater than about 400 nm, e.g., from about 475 nm to about 900 nm, examples of suitable photoinitiators include: camphorquinone, 4,4′-bis(diethylamino) benzophenone (Chivacure EMK from Chitec), 4,4′-bis(N,N′-dimethylamino) benzophenone (Michler's ketone), bis(2,4,6-trimethylbenzoyl)-phenylphosphineoxide (Irgacure 819 or BAPO from Ciba), metallocenes such as bis(eta 5-2-4-cyclopentadien-1-yl) bis[2,6-difluoro-3-(1H-pyrrol-1-yl) phenyl] titanium (Irgacure 784 from Ciba), and the visible light photoinitiators from Spectra Group Limited, Inc. such as H-Nu 470, H-Nu-535, H-Nu-635, H-Nu-Blue-640, and H-Nu-Blue-660.

A photosensitizer or co-initiator may be used to improve the activity of the cationic photoinitiator. It is for either increasing the rate of photoinitiated polymerization or shifting the wavelength at which polymerization occurs. The sensitizer used in combination with the above-mentioned cationic photoinitiator is not particularly limited. A variety of compounds can be used as photosensitizers, including heterocyclic and fused-ring aromatic hydrocarbons, organic dyes, and aromatic ketones. Examples of sensitizers include compounds disclosed by J. V. Crivello in Advances in Polymer Science, 62, 1 (1984), and by J. V. Crivello & K. Dietliker, “Photoinitiators for Cationic Polymerization” in Chemistry & technology of UV & EB formulation for coatings, inks & paints. Volume III, Photoinitiators for free radical and cationic polymerization. by K. Dietliker; [Ed. by P. K. T. Oldring], SITA Technology Ltd, London, 1991. Specific examples include polyaromatic hydrocarbons and their derivatives such as anthracene, pyrene, perylene and their derivatives, thioxanthones, α-hydroxyalkylphenones, 4-benzoyl-4′-methyldiphenyl sulfide, acridine orange, and benzoflavin.

There are a large number of known and technically proven cationic photoinitiators that are suitable. They include, for example, onium salts with anions of weak nucleophilicity. Examples are halonium salts, iodosyl salts or sulfonium salts, such as are described in published European patent application EP 153904 and WO 98/28663, sulfoxonium salts, such as described, for example, in published European patent applications EP 35969, 44274, 54509, and 164314, or diazonium salts, such as described, for example, in U.S. Pat. Nos. 3,708,296 and 5,002,856. All eight of these disclosures are hereby incorporated in their entirety by reference. Other cationic photoinitiators are metallocene salts, such as described, for example, in published European applications EP 94914 and 94915, which are both hereby incorporated in their entirety by reference.

A survey of other current onium salt initiators and/or metallocene salts can be found in “UV Curing, Science and Technology”, (Editor S. P. Pappas, Technology Marketing Corp., 642 Westover Road, Stamford, Conn., U.S.A.) or “Chemistry & Technology of UV & EB Formulation for Coatings, Inks & Paints”, Vol. 3 (edited by P. K. T. Oldring).

Suitable ferrocene type cationic photoinitiators include, for example, di(cyclopentadienyliron)arene salt compounds of formula (I) as disclosed in Chinese Patent No. CN 101190931:

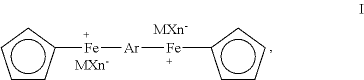

wherein anion MXn is selected from BF4, PF6, SbF6, AsF6, (C6F5)4B, ClO4, CF3SO3, FSO3, CH3SO3, C4F9SO3, and Ar is a fused ring or polycyclic arene.

Other illustrative ferrocene type cationic photoinitiators include, for example,(η6-Carbazole) (η5-cyclopenta-dienyl) iron hexafluorophosphate salts, specifically [cyclopentadiene-Fe—N-butylcarbazole]hexafluoro-phosphate (C4-CFS PF6) and [cyclopentadiene-Fe—N-octyl-carbazole]hexafluorophosphate (C8-CFS PF6), bearing C4 and C8 alkyl chains, respectively, on the nitrogen atom (see Polymer Eng. & Science (2009), 49(3), 613-618); ferrocenium dication salts, e.g., biphenyl bis[(η-cyclopentadienyl) iron] hexafluorophosphate ([bis(Cp—Fe)-biphenyl] (PF6)2) and straight cyclopentadien-iron-biphenyl hexafluorophosphate ([Cp—Fe-biphenyl]+PF6−) as disclosed in Chinese J. Chem. Engnrng (2008), 16(5), 819-822 and Polymer Bulltn (2005), 53(5-6), 323-331; cyclopentadienyl-Fe-carbazole hexafluorophosphate ([Cp—Fe-carbazole]+PF6−), cyclopentadienyl-Fe—N-ethylcarbazole hexafluorophosphate ([Cp—Fe-n-ethylcarbazole]+PF6—) and cyclopentadienyl -Fe-aminonaphthalene hexafluorophosphate ([Cp—Fe-aminonaphthalene]+PF6—) as disclosed in J Photochem. & Photobiology, A: Chemistry (2007), 187(2-3), 389-394 and Polymer Intnl (2005), 54(9), 1251-1255; alkoxy-substituted ferrocenium salts, for example, [cyclopendadien-Fe-anisole]PF6, [cyclopendadien-Fe-anisole]BF4, [cyclopendadien-Fe-diphenylether]PF6, [cyclo-pendadien-Fe-diphenylether]BF4, and [cyclopendadien-Fe-diethoxy-benzene]PF6, as disclosed in Chinese J. of Chem Engnrng (2006), 14(6), 806-809; cyclopentadiene-iron-arene tetrafluoroborates, for example, cyclopentadiene-iron-naphthalene tetrafluoroborate ([Cp—Fe-Naph] BF4) salt, as disclosed in Imaging Science J (2003), 51(4), 247-253; ferrocenyl tetrafluoroborate ([Cp—Fe-CP]BF4), as disclosed in Ganguang Kexue Yu Guang Huaxue (2003), 21(1), 46-52; [CpFe(η6-tol)]BF4, as disclosed in Ganguang Kexue Yu Guang Huaxue (2002), 20(3), 177-184, Ferrocenium salts (η6-α-naphthoxybenzene) (η5-cyclopentadienyl) iron hexafluorophosphate (NOFC-1) and (η6-β-naphthoxybenzene) (η5-cyclopentadienyl) iron hexafluorophosphate (NOFC-2), as disclosed in Int. J of Photoenergy (2009), Article ID 981065; (η6-Diphenyl-methane) (η5-cyclopentadienyl) iron hexafluorophosphate and (η6-benzophenone) (η5-cyclopenta-dienyl) iron hexafluorophosphate, as disclosed in Progress in Organic Coatings (2009), 65(2), 251-256; [CpFe(η6-isopropyl-benzene)]PF6, as disclosed in Chem Comm (1999), (17), 1631-1632; and any combination thereof.

Suitable onium type cationic photoinitiators include, for example, iodonium and sulfonium salts, as disclosed in Japanese Patent JP 2006151852. Other illustrative onium type photoinitiators include, for example, onium salts such as, diaryliodonium salts, triarylsulfonium salts, aryl-diazonium salts, ferrocenium salts, diarylsulfoxonium salts, diaryl-iodoxonium salts, triaryl-sulfoxonium salts, dialkylphenacyl-sulfonium salts, dialkylhydroxy-phenylsulfonium salts, phenacyl-triarylphosphonium salts, and phenacyl salts of heterocyclic nitrogen-containing compounds, as disclosed in U.S. Pat. Nos. 5,639,413; 5,705,116; 5,494618; 6,593,388; and Chemistry of Materials (2002), 14(11), 4858-4866; aromatic sulfonium or iodonium salts as disclosed in U.S. Patent Application No. 2008/0292993; diaryl-, triaryl-, or dialkylphenacylsulfonium salts, as disclosed in US2008260960 and J. Poly Sci, Part A (2005), 43(21), 5217; diphenyl-iodonium hexafluorophosphate (Ph2I+PF6−), as disclosed in Macromolecules (2008), 41(10), 3468-3471; onium salts using onium salts using less toxic anions to replace, e.g., SbF6-. Mentioned are anions: B(C6F5)4−, Ga(C6F5)4− and perfluoroalkyl fluorophosphate, PFnRf(6-n)−, as disclosed in Nettowaku Porima (2007), 28(3), 101-108; Photoactive allyl ammonium salt (BPEA) containing benzophenone moiety in the structure, as disclosed in Eur Polymer J (2002), 38(9), 1845-1850; 1-(4-Hydroxy-3-methylphenyl) tetrahydrothiophenium hexafluoroantimonate, as disclosed in Polymer (1997), 38(7), 1719-1723; and any combination thereof.

Illustrative iodonium type cationic photoinitiators include, for example, diaryliodonium salts having counterions like hexafluoro-phosphate and the like, such as, for example, (4-n-pentadecyloxy-phenyl)phenyliodonium hexa-fluoroantimonate, as disclosed in US2006041032; diphenyliodonium hexafluorophosphate, as disclosed in U.S. Pat. No. 4,394,403 and Macromolecules (2008), 41(2), 295-297; diphenyliodonium ions as disclosed in Polymer (1993), 34(2), 426-8; Diphenyliodonium salt with boron tetrafluoride (Ph2I+BF4−), as disclosed in Yingyong Huaxue (1990), 7(3), 54-56; SR-1012, a diaryldiodonium salt, as disclosed in Nuclear Inst. & Methods in Physics Res, B (2007), 264(2), 318-322; diaryliodonium salts, e.g., 4,4′-di-tert-butyldiphenyl-iodonium hexafluoroarsenate, as disclosed in J Polymr Sci, Polymr Chem Edition (1978), 16(10), 2441-2451; Diaryliodonium salts containing complex metal halide anions such as diphenyliodonium fluoroborate, as disclosed in J Polymr Sci, Poly Sympos (1976), 56, 383-95; and any combination thereof.

Illustrative sulfonium type cationic photoinitiators include, for example, UVI 6992 (sulfonium salt) as disclosed in Japanese patent JP2007126612; compounds of the formula:

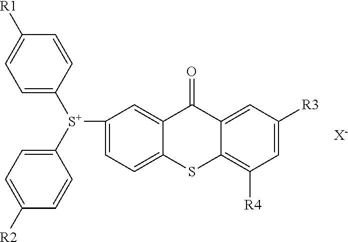

where R1-2=F; R3=isopropyl; R4=H; X=PF6, as disclosed in Japanese patent JP10101718; thioxanthone-based sulfonium salts, e.g., of the formula:

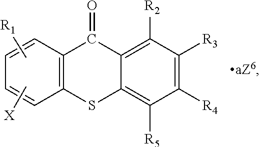

as disclosed in U.S. Pat. No. 6,054,501; (Acyloxyphenyl)sulfonium salts of the type R₃−xS+R3x A−, where A− is a non-nucleophilic anion such as AsF₆−, and R3 may be the phenyl group shown below:

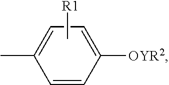

as disclosed in U.S. Pat. No. 5,159,088; 9,10-dithiophenoxyanthracene alkyldiarylsulfonium salts, e.g., ethylphenyl(9-thiophenoxy-anthracenyl-10) sulfonium hexafluoroantimonate, and the like, as disclosed in U.S. Pat. No. 4,760,013; etc.; triphenylsulfonium hexafluorophosphate salt, as disclosed in U.S. Pat. No. 4,245,029; S,S-dimethyl-S-(3,5-dimethyl-2-hydroxyphenyl)sulfonium salts, as disclosed in J Poly Sci, Part A (2003), 41(16), 2570-2587; Anthracene-bound sulfonium salts, as disclosed in J Photochem & Photobiology, A: Chemistry (2003), 159(2), 161-171; triarylsulfonium salts, as disclosed in J Photopolymer Science & Tech (2000), 13(1), 117-118 and J Poly Science, Part A (2008), 46(11), 3820-29; S-aryl-S,S-cycloalkylsulfonium salts, as disclosed in J Macromol Sci, Part A (2006), 43(9), 1339-1353; dialkylphenacylsulfonium salts, as disclosed in UV & EB Tech Expo & Conf, May 2-5, 2004, 55-69 and ACS Symp Ser (2003), 847, 219-230; Dialkyl(4-hydroxyphenyl)sulfonium salts, and their isomeric dialkyl(2-hydroxyphenyl)sulfonium salts, as disclosed in ACS 224th Natnl Meeting, Aug. 18-22, 2002, POLY-726; Dodecyl(4-hydroxy-3,5-dimethylphenyl)methylsulfonium hexafluorophosphate and similar alkyl analogs other than dodecyl. Tetrahydro-1-(4-hydroxy-3,5-dimethylphenyl)thiophenium hexafluorophosphate and tetrahydro-1-(2-hydroxy-3,5-dimethylphenyl)thiophenium hexafluorophosphate, as disclosed in ACS Polymer Preprints (2002), 43(2), 918-919; photoinitiators with the general structure Ar′S+CH3(C12H25)SbF6−, where Ar′ is phenacyl (I), 2-indanonyl (II), 4-methoxyphenacyl (III), 2-naphthoylmethyl (IV), 1-anthroylmethyl (V), or 1-pyrenoylmethyl (VI), as disclosed in J Polymr Sci, Part A (2000), 38(9), 1433-1442; Triarylsulfonium salts Ar3S+MXn− with complex metal halide anions such as BF4−, AsF6−, PF6−, and SbF6−, as disclosed in J Polymr Sci, Part A (1996), 34(16), 3231-3253; Dialkylphenacylsulfonium and dialkyl(4-hydroxyphenyl) sulfonium salts, as disclosed in Macromolecules (1981), 14(5), 1141-1147; Triarylsulfonium salts R2R1S+MFn− (R, R1=Ph or substituted phenyl; M=B, As, P; n=4 or 6) and the sulfonium salt of formula (I):

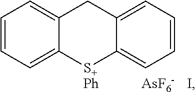

as disclosed in J. Polymr. Sci, Polymr Chem Edition (1979), 17(4), 977-99; aromatic sulfonium salts with, e.g., PF6− anion, e.g., UVI 6970, as disclosed in JP 2000239648; and any combination thereof.

Suitable pyridinium type cationic photoinitiators include, for example, N-ethoxy 2-methylpyridinium hexafluorophosphate (EMP+PF6−), as disclosed in Turkish J of Chemistry (1993), 17(1), 44-49; Charge-transfer complexes of pyridinium salts and aromatic electron donors (hexamethyl-benzene and 1,2,4-trimethyoxy-benzene), as disclosed in Polymer (1994), 35(11), 2428-31; N,N′-diethoxy-4,4′-azobis(pyridinium) hexafluorophosphate (DEAP), as disclosed in Macromolecular Rapid Comm (2008), 29(11), 892-896; and any combination thereof.

Other suitable cationic photoinitiators include, for example, Acylgermane based photoinitiator in the presence of onium salts, e.g., benzoyltrimethylgermane (BTG) and onium salts, such as diphenyl-iodonium hexafluorophosphate (Ph2I+PF6−) or N-ethoxy-2-methyl-pyridinium hexafluorophosphate (EMP+PF6−), as disclosed in Macromolecules (2008), 41(18), 6714-6718; Di-Ph diselenide (DPDS), as disclosed in Macromolecular Symposia (2006), 240, 186-193; N-phenacyl-N,N-dimethyl-anilinium hexafluoroantimonate (PDA+SbF6−), as disclosed in Macromol Rapid Comm (2002), 23(9), 567-570; Synergistic blends of: diaryliodonium hexafluoro-antimonate (IA) with tolylcumyl-iodonium tetrakis(pentafluoro-phenyl)borate (IB), and cumenecyclopentadienyliron(II) hexafluorophosphate with IA and IB, as disclosed in Designed Monomers and Polymers (2007), 10(4), 327-345; Diazonium salts, e.g., 4-(hexyloxy)-substituted diazonium salts with complex anions, as disclosed in ACS Symp Series (2003), 847, 202-212; 5-Arylthianthrenium salts, as disclosed in J Poly Sci, Part A (2002), 40(20), 3465-3480; and any combination thereof.

Other suitable cationic photoinitiators include, for example, triarylsulfonium salts such as triarylsulfonium borates modified for absorbing long wavelength UV. Illustrative examples of such modified borates include, for example, SP-300 available from Denka, tris(4-(4-acetylphenyl)thiophenyl)sulfonium tetrakis(pentafluorophenyl)borate (GSID4480-1 or Irgacure PAG-290) available from Ciba/BASF, and those photoinitiators disclosed in WO1999028295; WO2004029037; WO2009057600; U.S. Pat. No. 6,368,769 WO2009047105; WO2009047151; WO2009047152; US 20090208872; and U.S. Pat. No. 7,611,817.

Preferred cationic photoinitiators include a mixture of: bis[4-diphenylsulfoniumphenyl]sulfide bishexafluoroantimonate; thiophenoxyphenylsulfonium hexafluoroantimonate (available as Chivacure 1176 from Chitec); tris(4-(4-acetylphenyl)thiophenyl)sulfonium tetrakis(pentafluorophenyl)borate (GSID4480-1 from Ciba/BASF), iodonium, [4-(1-methylethyl)phenyl](4-methylphenyl)-,tetrakis(pentafluorophenyl)borate (available as Rhodorsil 2074 from Rhodia), 4-[4-(2-chlorobenzoyl)phenylthio]phenylbis(4-fluorophenyl)sulfonium hexafluoroantimonate (as SP-172) and SP-300 (both available from Adeka).

The liquid radiation curable resin composition can include any suitable amount of the cationic photoinitiator, for example, in certain embodiments, in an amount an amount up to about 50% by weight of the composition, in certain embodiments, up to about 20% by weight of the composition, and in further embodiments from about 1% to about 10% by weight of the composition. In a further embodiment, the amount of cationic photoinitiator is from about 0.25 wt % to about 8 wt % of the total composition, more preferably from about 1 wt % to about 6 wt %. In an embodiment, the above ranges are particularly suitable for use with epoxy monomers.

In accordance with an embodiment, the liquid radiation curable resin composition can further include a chain transfer agent, particularly a chain transfer agent for a cationic monomer. The chain transfer agent has a functional group containing active hydrogen. Examples of the active hydrogen-containing functional group include an amino group, an amide group, a hydroxyl group, a sulfo group, and a thiol group. In an embodiment, the chain transfer agent terminates the propagation of one type of polymerization, i.e., either cationic polymerization or free-radical polymerization and initiates a different type of polymerization, i.e., either free-radical polymerization or cationic polymerization. In accordance with an embodiment, chain transfer to a different monomer is a preferred mechanism. In embodiments, chain transfer tends to produce branched molecules or crosslinked molecules. Thus, chain transfer offers a way of controlling the molecular weight distribution, crosslink density, thermal properties, and/or mechanical properties of the cured resin composition.

Any suitable chain transfer agent can be employed. For example, the chain transfer agent for a cationic polymerizable component is a hydroxyl-containing compound, such as a compound containing 2 or more than 2 hydroxyl-groups. In an embodiment, the chain transfer agent is selected from the group consisting of a polyether polyol, polyester polyol, polycarbonate polyol, ethoxylated or propoxylated aliphatic or aromatic compounds having hydroxyl groups, dendritic polyols, hyperbranched polyols. An example of a polyether polyol is a polyether polyol comprising an alkoxy ether group of the formula [(CH₂)ₙO]ₘ, wherein n can be 1 to 6 and m can be 1 to 100.

A particular example of a chain transfer agent is polytetrahydrofuran such as TERATHANE™.

The liquid radiation curable resin composition can include any suitable amount of the chain transfer agent, for example, in certain embodiments, in an amount up to about 50% by weight of the composition, in certain embodiments, up to about 30% by weight of the composition, and in certain other embodiments from about 10% to about 20% by weight of the composition.

The liquid radiation curable resin composition of the invention can further include one or more additives selected from the group consisting of bubble breakers, antioxidants, surfactants, acid scavengers, pigments, dyes, thickeners, flame retardants, silane coupling agents, ultraviolet absorbers, resin particles, core-shell particle impact modifiers, soluble polymers and block polymers, organic, inorganic, or organic-inorganic hybrid fillers of sizes ranging from 8 nanometers to about 50 microns.

Stabilizers are often added to the compositions in order to prevent a viscosity build-up, for instance a viscosity build-up during usage in a solid imaging process. In an embodiment, stabilizers include those described in U.S. Pat. No. 5,665,792, the entire disclosure of which is hereby incorporated by reference. Such stabilizers are usually hydrocarbon carboxylic acid salts of group IA and IIA metals. In other embodiments, these salts are sodium bicarbonate, potassium bicarbonate, and rubidium carbonate. Rubidium carbonate is preferred for formulations of this invention with recommended amounts varying between 0.0015 to 0.005% by weight of composition. Alternative stabilizers include polyvinylpyrrolidones and polyacrylonitriles. Other possible additives include dyes, pigments, fillers (e.g. silica particles—preferably cylindrical or spherical silica particles—, talc, glass powder, alumina, alumina hydrate, magnesium oxide, magnesium hydroxide, barium sulfate, calcium sulfate, calcium carbonate, magnesium carbonate, silicate mineral, diatomaceous earth, silica sand, silica powder, titanium oxide, aluminum powder, bronze powder, zinc powder, copper powder, lead powder, gold powder, silver dust, glass fiber, titanic acid potassium whisker, carbon whisker, sapphire whisker, beryllia whisker, boron carbide whisker, silicon carbide whisker, silicon nitride whisker, glass beads, hollow glass beads, metaloxides and potassium titanate whisker), antioxidants, wetting agents, photosensitizers for the free-radical photoinitiator, chain transfer agents, leveling agents, defoamers, surfactants and the like.

In accordance with an embodiment of the invention, the liquid radiation curable resin composition contains the polymerizable components such that the desired photosensitivity is obtained by choosing an appropriate ratio of the initiators and/or polymerizable components. The ratio of the components and of the initiators affect the photosensitivity, speed of curing, degree of curing, crosslink density, thermal properties (e.g., T_{g}), and/or mechanical properties (e.g., tensile strength, storage modulus, loss modulus) of the liquid radiation curable resin composition or of the cured article.

Accordingly, in an embodiment, the ratio by weight of cationic photoinitiator to free-radical photoinitiator (CPI/RPI) is less than about 4.0, preferably from about 0.1 to about 2.0, and more preferably from about 0.2 to about 1.0.

In accordance with an embodiment, the liquid radiation curable resin composition has a ratio by weight of cationic polymerizable component to free-radical polymerizable component (CPC/RPC) is less than about 7.0, or less than about 5.0, e.g., from about 0.5 to about 2.0, and more preferably from about 1.0 to about 1.5.

The second aspect of the instant claimed invention is a method of forming via additive fabrication a three-dimensional article capable of changing color comprising: (1) heating a liquid radiation curable resin, thereby forming a liquid radiation curable resin having an increased depth of penetration (Dp); (2) establishing a first liquid layer of the liquid radiation curable resin having the increased Dp; (3) exposing the first liquid layer imagewise to actinic radiation to form an imaged cross-section, thereby forming a first cured layer; (4) forming a new layer of liquid radiation curable resin having the increased Dp in contact with the first cured layer; (5) exposing said new layer imagewise to actinic radiation to form an additional cured layer; and (6) repeating steps (4) and (5) a sufficient number of times in order to build up a three-dimensional article; wherein the liquid radiation curable resin further comprises at least one thermochromic component having an activation temperature and a terminal activation temperature, such that the thermochromic component changes from a colored state to a partially colored state at the activation temperature, and to a substantially colorless state at the terminal activation temperature; and at least one non-thermochromic pigment or dye, such that the liquid radiation curable resin or three-dimensional article changes from a first colored state to a second colored state at the activation temperature, and to a third colored state at the terminal activation temperature.

A particularly suitable way to induce Dp increases into a resin having a thermochromic component possessing an activation temperature and a terminal activation temperature is to heat the liquid radiation curable resin into which it is incorporated. Such heating can be done selectively or uniformly, although in a preferred embodiment, the heating is employed uniformly. In an embodiment of the second aspect of the instant claimed invention, the liquid radiation curable resin comprises both a thermochromic component and at least one non-thermochromic pigment or dye. The non-thermochromic pigment or dye is not visually responsive to changes in environmental conditions, such as temperature. Thus it is not a visual effect initiator. Such a component is added to establish a “baseline” color and/or opacity, or one which will remain even if the additional effects to the visual state or color imparted by the thermochromic component are removed.

In an embodiment of the second aspect of the instant claimed invention, the liquid radiation curable resin includes a thermochromic which possesses a color below its activation temperature, and gradually transitions to a colorless state from an increase in temperature from the activation temperature to the terminal activation temperature. By adding a baseline non-thermochromic component, the liquid radiation curable composition appears in a first colored state which is the result of the mix of colors exhibited by the thermochromic component and non-thermochromic component below the activation temperature. Then, as the thermochromic component begins to transition from a first color to substantially colorless between the activation temperature and the terminal activation temperature, the resin will appear in a second colored state. Finally, in this embodiment, once the terminal activation temperature has been reached, the thermochromic component would appear substantially colorless, leaving the resulting resin to have a color only of the non-thermochromic pigment or dye.

Take, for example, a situation in which the thermochromic component appears blue below its activation temperature, and transitions to at least partially colorless at the activation temperature, and whereupon reaching the terminal activation point, it becomes substantially colorless. In this example, assume the non-thermochromic pigment or dye appears immutably yellow. At temperatures below the activation temperature, the resulting liquid radiation curable resin for additive fabrication into which the thermochromic component and the non-thermochromic pigment or dye were incorporated (in equal parts and strength) would appear green. If the resin were heated to the activation temperature, the thermochromic component would begin fading to clear, whereupon the resulting mixture would appear increasingly greenish-yellow as the resin were further heated. Then, upon heating the resin to the terminal activation point of the thermochromic component, the resin would appear yellow, as the only contribution to color would be provided by the yellow non-thermochromic pigment.

In an embodiment, the thermochromic component and non-thermochromic pigment or dye would each be a different primary color (red, blue, or yellow), whereupon the thermochromic component would transition to substantially colorless at above its terminal activation temperature. In such an embodiment, the resin would appear a secondary color (purple, orange, or green) below the activation temperature, then would gradually transition to the primary color of the non-thermochromic component from above the activation temperature to the terminal activation temperature of the thermochromic component.

In an embodiment, the thermochromic component and non-thermochromic pigment or dye are the same color below the activation temperature. In another embodiment, they are the same color at and above the terminal activation temperature. In an embodiment, the thermochromic component changes from one color to another color at its activation temperature. In another embodiment, the thermochromic component changes from one color to another color at its terminal activation temperature. In an embodiment, the thermochromic component changes from one color to at least partially colorless at its activation temperature. In another embodiment, the thermochromic component changes to a substantially colorless state at its terminal activation temperature.

If an increased range of colors and/or visual states are sought, it would be possible to stack additional thermochromic components having different activation temperatures, to impart in the liquid radiation curable resin, or the three-dimensional article cured therefrom, a multitude of color changing states (brought about by a concomitant number of different activation temperatures), such that a variety of colors could be experienced. In using such a resin in an additive fabrication process in which all thermochromic components transitioned to at least partially clear and/or colorless at their activation temperature, it might be useful, although not necessary, to heat the entire resin during the build to at least the highest activation temperature of all included thermochromic components, to maximize the increase in Dp, and thereby maximize the efficiency with which a three-dimensional article might be formed. However, by increasing the temperature to at least above the lowest associated activation temperature, the Dp would also be increased, if only slightly. The variable amount of heat applied could be used as a method to fine-tune the Dp of the associated resin in such a situation, as it would increase stepwise along each successively higher activation temperature.

The third aspect of the instant claimed invention is a method of forming via additive fabrication a three-dimensional article capable of color or opacity change comprising: (1) inducing an at least temporary change in a depth of penetration (Dp) of a liquid radiation curable resin, thereby forming a liquid radiation curable resin having an at least temporarily modified Dp, wherein the temporary change in the Dp is occasioned by subjecting the liquid radiation curable resin to an alteration in an environmental condition selected from the group consisting of heat, light, pH, magnetism, pressure, and electric current; (2) establishing a first liquid layer of the liquid radiation curable resin having the at least temporarily modified Dp; (3) exposing the first liquid layer imagewise to actinic radiation to form an imaged cross-section, thereby forming a first cured layer; (4) forming a new layer of liquid radiation curable resin having the at least temporarily modified Dp in contact with the first cured layer; (5) exposing said new layer imagewise to actinic radiation to form an additional imaged cross-section; and (6) repeating steps (4) and (5) a sufficient number of times in order to build up a three-dimensional article; wherein the liquid radiation curable resin further comprises a first visual effect initiator having a first activation point; such that during step (1), the first visual effect initiator component reaches the first activation point, thereby inducing a color or opacity change in the liquid radiation curable resin.

In an embodiment according to the third aspect of the instant invention, the change in the Dp of the liquid radiation curable resin for additive fabrication is modified by either increasing or decreasing it in response to a change in an environmental condition. Such an alteration might be occasioned by adjusting various environmental conditions such as, for example, the ambient temperature, light, pH, magnetism, pressure, or electric current.

While heretofore it has been noted that inducing an increase in a resin's Dp aids in the additive fabrication build process because of increases in energy efficiency and build speed, it may also be desirable at times to induce a decrease in a resin's Dp. This may occur in an extremely colorless and transparent resin, wherein actinic light from the curing source traverses the resin unimpeded to a depth too far to allow for construction of a three-dimensional article with sufficient resolution or accuracy. In such instances, it would be desirable to temporarily impart a Dp increase via an increase in the amount of color and/or opacity in the resin. These increases might occur when an incorporated visual effect initiator reaches a first activation point.

Additionally, in an embodiment, two or more visual effect initiators are incorporated into the liquid radiation curable resin. By incorporating more than one visual effect initiator into the liquid radiation curable resin, different levels of color and/or transparency can be achieved. In an embodiment, more than one visual effect initiator can be incorporated into the liquid radiation curable resin wherein the more than one visual effect initiators all have the same activation point in order to obtain unique combinations of color and/or transparency. In another embodiment, the visual effect initiators possess different activation points, such that multiple visual states are possible, as an alteration to an environmental condition occurs across the various activation points.

In an embodiment of the third aspect of the claimed invention, the visual effect initiator which imparts a change to the visual state of the liquid radiation curable resin similarly is capable of imparting the same change to the visual state of the three-dimensional article cured therefrom. In such an embodiment, the liquid radiation curable resin is capable of undergoing changes in a visual state at the activation point of its associated visual effect initiator in response to the same change in the environmental condition, such as heat, light, pH, pressure, magnetism, or electric current, even after curing, and whereupon the part build has been completed.

According to step (3) of the third aspect of the present invention, in some embodiments, the light source used to provide actinic radiation to cure the liquid radiation curable resin is a laser such as a He—Cd laser or an Argon ion laser. Such lasers are common on commercially available stereolithography machines and known in the art. In other embodiments, the light source is a light-emitting diode (LED). In other embodiments, the light source is a lamp. In still further embodiments, the light is delivered to the liquid radiation curable resin using an image produced from a DMD (digital micromirror device) chip or LCD display. At least two intensities can be created by a single light source or by multiple light sources. In an embodiment, a single light source is used. In another embodiment, a second light source is used in combination with the first light source to increase the light intensity delivered to certain areas of the radiation curable resin.

The fourth aspect of the instant claimed invention is a three-dimensional object formed by the method of the first, second, or third aspect of the instant claimed invention.

All references, including publications, patent applications, and patents, cited herein are hereby incorporated by reference to the same extent as if each reference were individually and specifically indicated to be incorporated by reference and were set forth in its entirety herein.

The use of the terms “a” and “an” and “the” and similar referents in the context of describing the invention (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Preferred embodiments of this invention are described herein, including the best mode known to the inventors for carrying out the invention. Variations of those preferred embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

While the invention has been described in detail and with reference to specific embodiments thereof, it will be apparent to one of ordinary skill in the art that various changes and modifications can be made therein without departing from the spirit and scope of the claimed invention.

1. A method of forming a three-dimensional article via additive fabrication comprising:
(1) inducing an increase in a depth of penetration (Dp) of a radiation curable resin, thereby forming a radiation curable resin having an increased Dp;
(2) establishing a layer of the radiation curable resin having the increased Dp;
(3) exposing the layer imagewise to actinic radiation to form an imaged cross-section, thereby forming a cured layer;
(4) forming a new layer of radiation curable resin having the increased Dp in contact with the cured layer;
(5) exposing said new layer imagewise to actinic radiation to form an additional cured layer; and
(6) repeating steps (4) and (5) a sufficient number of times in order to build up a three-dimensional article.

2. The method of claim 1, wherein the radiation curable resin comprises a. thermochromic component having an activation temperature and a terminal activation temperature.

3. The method of claim 2, wherein the step of inducing an increase in the depth of penetration (Dp) is achieved by heating the thermochromic component to at least the activation temperature to induce in the radiation curable resin a change from a colored state to a partially colorless state.

4. The method of claim 3, further comprising the additional step of:
(7) cooling the three-dimensional article to below the activation temperature to induce in the three-dimensional article a return from the partially colorless state to the colored state.

5. The method of claim 4, wherein an amount of actinic radiation required to form the additional imaged cross-section is less than if the thermochromie component were not heated above the activation temperature.

6. The method of claim 5, further comprising the additional steps of:
(8) heating at least one portion of the three-dimensional article to above the activation temperature to induce in the at least one portion of the three-dimensional article a change from the colored state back to the partially colorless state;
(9) optionally, repeating steps (7) and (8) a plurality of times, to occasion changes from a partially colorless state to a colored state and back as many times as desired.

7. The method of claim 6, further comprising the additional step of:
(10) heating further the at least one portion of the three-dimensional article from the activation temperature to the terminal activation temperature to induce in the at least one portion of the three-dimensional article a change from the partially colorless state to a substantially colorless state; and
(11) optionally, cooling the at least one portion of the three-dimensional article to below the terminal activation temperature to induce in the three-dimensional article a change from the substantially colorless state to the partially colorless state or the colored state.

8. The method of claim 7, wherein the activation temperature is from about 20 degrees Celsius to about 75 degrees Celsius, more preferably, from about 30 degrees Celsius to about 43 degrees Celsius, more preferably from about 31 degrees Celsius to about 35 degrees Celsius.

9. The method of claim 8, wherein the difference between the terminal activation temperature and the activation temperature is from between about 2 to about 10 degrees Celsius.

10. The method of claim 9, wherein the thermochromic component is reversible and does not possess a locking temperature.

11. The method of claim 10, wherein the thermochromic component is present in an amount from about 0.005 wt % to about 5 wt %, more preferably from about 0.005 wt % to about 2 wt %, more preferably from about 0.5 wt % to about 1 wt %.

12. The method of claim 11, wherein the thermochromic component comprises a thermally sensitive pigment or dye encased in an acid-impermeable microcapsule.

13. The method of claim 12, wherein below the activation temperature, the thermally sensitive pigment or dye is a color selected from the group consisting of black, red, orange, yellow, green, blue, indigo, violet, and white.

14. The method of claim 13, wherein the thermochromic component further comprises a halochromic component encased in the acid-impermeable microcapsule.

14. A method of forming via additive fabrication a three-dimensional article capable of changing color comprising:
(1) heating a liquid radiation curable resin, thereby forming a liquid radiation curable resin having an increased depth of penetration (Dp);
(2) establishing a first liquid layer of the liquid radiation curable resin having the increased Dp;
(3) exposing the first liquid layer imagewise to actinic radiation to form an imaged cross-section, thereby forming a first cured layer;
(4) forming a new layer of liquid radiation curable resin having the increased Dp in contact with the first cured layer;
(5) exposing said new layer imagewise to actinic radiation to form an additional cured layer; and
(6) repeating steps (4) and (5) a sufficient number of times in order to build up a three-dimensional article;
wherein the liquid radiation curable resin further comprises
at least one thermochromic component having an activation temperature and a terminal activation temperature, such that the thermochromic component changes from a colored state to a partially colored state at the activation temperature, and to a substantially colorless state at the terminal activation temperature; and
at least one non-thermochromic pigment or dye, such that the liquid radiation curable resin or three-dimensional article changes from a first colored state to a second colored state at the activation temperature, and to a third colored state at the terminal activation temperature.

16. The method of claim 15, wherein the thermochromic component is red, blue, or yellow;
the non-thermochromic pigment is red, blue, or yellow;
the thermochromic component and the non-thermochromic components are not the same color;
below the activation temperature, the liquid radiation curable resin is purple, orange, or green; and
at and above the terminal activation temperature, the liquid radiation curable resin is red, blue, or yellow.

17. A method of forming via additive fabrication a three-dimensional article capable of color or opacity change, comprising:
(1) inducing an at least temporary change in a depth of penetration (Dp) of a liquid radiation curable resin, thereby forming a liquid radiation curable resin having an at least temporarily modified Dp, wherein the temporary change in the Dp is occasioned by subjecting the liquid radiation curable resin to an alteration in an environmental condition selected from the group consisting of heat, light, pH, magnetism, pressure, and electric current;
(2) establishing a first liquid layer of the liquid radiation curable resin having the at least temporarily modified Dp;
(3) exposing the first liquid layer imagewise to actinic radiation to form an imaged cross-section, thereby forming a first cured layer;
(4) forming a new layer of liquid radiation curable resin having the at least temporarily modified Dp in contact with the first cured layer;
(5) exposing said new layer imagewise to actinic radiation to form an additional imaged cross-section; and
(6) repeating steps (4) and (5) a sufficient number of times in order to build up a three-dimensional article;
wherein the liquid radiation curable resin further comprises a first visual effect initiator having a first activation point;
such that during step (1), the first visual effect initiator component reaches the first activation point, thereby inducing a color or opacity change in the liquid radiation curable resin.

18. The method of claim 17, wherein the liquid radiation curable resin additionally comprises a second visual effect initiator having a second activation point which is different than the first activation point;
such that, during step (1), the liquid radiation curable resin changes from a first colored state to a second colored state at the first activation point of the first visual effect initiator, and is capable of changing to a third colored state if the second visual effect initiator reaches the second activation point.

19. The three-dimensional object formed by the method of claim 18.

20. The three-dimensional object of claim 19, wherein the three-dimensional article exhibits the first colored state below the first activation point, the second colored state from the first activation point to below the second activation point, and the third colored state at and above the second activation point.
